(19) United States
(12) Patent Application Publication
(10) Pub. No.: US 2023/0099612 A1
(43) Pub. Date: Mar. 30, 2023

(54) TREATMENT LIQUID, CHEMICAL MECHANICAL POLISHING METHOD, AND METHOD FOR TREATING SEMICONDUCTOR SUBSTRATE

(71) Applicant: FUJIFILM Corporation, Tokyo (JP)

(72) Inventor: Tetsuya Kamimura, Haibara-gun (JP)

(73) Assignee: FUJIFILM Corporation, Tokyo (JP)

(21) Appl. No.: 17/965,554

(22) Filed: Oct. 13, 2022

Related U.S. Application Data
(63) Continuation of application No. PCT/JP2021/010000, filed on Mar. 12, 2021.

(30) Foreign Application Priority Data
Apr. 16, 2020 (JP) 2020-073261
Jul. 9, 2020 (JP) 2020-118322

(51) Int. Cl. C09G 1/02; H01L 21/306

(52) U.S. Cl. CPC C09G 1/02; H01L 21/30625

(57) ABSTRACT

An object of the present invention is to provide a treatment liquid for a semiconductor substrate, which has excellent corrosion prevention performance for a metal-containing layer. In addition, another object of the present invention is to provide a chemical mechanical polishing method and a method for treating a semiconductor substrate.

The treatment liquid of an embodiment of the present invention is a treatment liquid for a semiconductor substrate, which includes a component A having two or more onium structures in the molecule and water, and has a pH of 6.0 to 13.5 at 25° C.

### CROSS-REFERENCE TO RELATED APPLICATIONS

This application is a Continuation of PCT International Application No. PCT/JP2021/010000 filed on Mar. 12, 2021, which claims priority under 35 U.S.C. § 119(a) to Japanese Patent Application No. 2020-073261 filed on Apr. 16, 2020 and Japanese Patent Application No. 2020-118322 filed on Jul. 9, 2020. Each of the above applications is hereby expressly incorporated by reference, in its entirety, into the present application.

### BACKGROUND OF THE INVENTION

### 1. Field of the Invention

The present invention relates to a treatment liquid for a semiconductor substrate, a chemical mechanical polishing method, and a method for treating a semiconductor substrate.

### 2. Description of the Related Art

Semiconductor elements such as charge-coupled devices (CCD) and memories are manufactured by forming fine electronic circuit patterns on a substrate, using photolithography technology. More specifically, the semiconductor elements are manufactured by forming a resist film on a laminate that has a metal film serving as a wiring line material, an etching stop layer, and an interlayer insulating layer on a substrate, and carrying out a photolithography step and a dry etching step (for example, a plasma etching treatment).

In the manufacture of these semiconductor elements, a chemical mechanical polishing (CMP) treatment in which a surface of a substrate having a metal wire film, a barrier film, an insulating film, or the like is flattened using a polishing slurry including polishing fine particles (for example, silica and alumina) may be performed.

In addition, dry etching residues (for example, metal components such as a titanium-based metal derived from a metal hard mask or an organic component derived from a photoresist film) may remain on a substrate which has been subjected to the manufacturing step. In particular, in a substrate which has been subjected to a CMP treatment, polishing fine particles to be used in the CMP treatment, a polished wiring line metal film, and/or a metal component derived from a barrier film and the like easily remain on a surface of a semiconductor substrate after polishing.

Since these residues can short-circuit wiring lines and affect the electrical characteristics of a semiconductor, a step of removing these residues from a surface of the semiconductor substrate is often performed.

For example, JP2008-528762A describes a composition for treating an ultra-small electronic device structure, in which the composition includes (i) an alkanolamine, (ii) a quaternary ammonium hydroxide, and (iii) a specific complexing agent.

### SUMMARY OF THE INVENTION

The present inventors have examined a treatment liquid for a semiconductor substrate with reference to JP2008-528762A and the like, and have thus found that there is room for further improvement in corrosion prevention performance for a metal-containing layer serving as a wiring line material, a plug material, an insulating layer, and the like with regard to the treatment liquid.

Therefore, an object of the present invention to is provide a treatment liquid for a semiconductor substrate, in which the treatment liquid has excellent corrosion prevention performance for a metal-containing layer.

In addition, another object of the present invention is to provide a chemical mechanical polishing method and a method for treating a semiconductor substrate.

The present inventors have found that the objects can be accomplished by the following configurations.

[1] A treatment liquid for a semiconductor substrate, comprising:

a component A having two or more onium structures in a molecule; and water,

in which the treatment liquid has a pH of 6.0 to 13.5 at 25° C.

[2] The treatment liquid as described in [1],

in which the onium structure is a structure selected from the group consisting of an ammonium structure, a phosphonium structure, and a sulfonium structure.

[3] The treatment liquid as described in [1] or [2],

in which the onium structure is a structure selected from the group consisting of an ammonium structure and a phosphonium structure.

[4] The treatment liquid as described in any one of [1] to [3],

in which the onium structure is an ammonium structure.

[5] The treatment liquid as described in any one of [1] to [3],

in which the component A is a compound represented by General Formula (I) or (II) which will be described later.

[6] The treatment liquid as described in [5],

in which in General Formulae (I) and (II), n represents 2 and X^{(2/n)-} represents a hydroxide ion.

[7] The treatment liquid as described in [5] or [6],

in which the component A is the compound represented by General Formula (I).

[8] The treatment liquid as described in any one of [1] to [7],

in which a content of the component A is 0.1% to 5% by mass with respect to a total mass of the treatment liquid.

[9] The treatment liquid as described in any one of [1] to [8], further comprising an organic acid or an organic alkali.

[10] The treatment liquid as described in any one of [1] to [9], further comprising an anticorrosive agent.

[11] The treatment liquid as described in [10],

in which the anticorrosive agent includes a heteroaromatic compound.

[12] The treatment liquid as described in [11],

in which the heteroaromatic compound is at least one selected from the group consisting of a tetrazole compound, a triazole compound, an imidazole compound, and a pyrazole compound.

[13] The treatment liquid as described in any one of [10] to [12],

in which the anticorrosive agent includes at least one hydroxylamine compound selected from the group consisting of hydroxylamine, a hydroxylamine derivative, and salts thereof.

[14] The treatment liquid as described in any one of [1] to [13], further comprising an organic solvent.

[15] The treatment liquid as described in any one of [1] to [14], further comprising a surfactant.

[16] The treatment liquid as described in any one of [1] to [15],

in which the semiconductor substrate has a metal-containing substance including at least one selected from the group consisting of copper, tungsten, and cobalt.

[17] The treatment liquid as described in any one of [1] to [16], further comprising colloidal silica.

[18] The treatment liquid as described in any one of [1] to [17], further comprising colloidal silica having an average primary particle diameter of 3 to 20 nm.

[19] A chemical mechanical polishing method comprising a step of bringing a surface to be polished of an object to be polished into contact with a polishing pad attached to a polishing platen while supplying the treatment liquid as described in [17] or [18] to the polishing pad, and relatively moving the object to be polished and the polishing pad to polish the surface to be polished to obtain a polished object to be polished.

[20] A method for treating a semiconductor substrate, comprising:

a step of removing a metal-containing substance on the semiconductor substrate using the treatment liquid as described in any one of [1] to [16].

According to the present invention, it is possible to provide a treatment liquid for a semiconductor substrate, which has excellent corrosion prevention performance for a metal-containing layer.

In addition, according to the present invention, it is possible to provide a chemical mechanical polishing method and a method for treating a semiconductor substrate.

### DESCRIPTION OF THE PREFERRED EMBODIMENTS

Hereinafter, an example of a form for carrying out the present invention will be described.

Descriptions on the configuration requirements which will be described later are made based on representative embodiments of the present invention in some cases, but it should not be construed that the present invention is limited to such embodiments.

In the present specification, a numerical value range expressed using “to” means a range that includes the preceding and succeeding numerical values of “to” as the lower limit value and the upper limit value, respectively.

In the present specification, a reference to “preparation” is meant to encompass delivering a predetermined material by purchases or the like, in addition to comprising specific materials by synthesis, combination, or the like.

In the present specification, in a case where two or more kinds of a certain component are present, the “content” of the component means a total content of the two or more kinds of the components.

The compounds described in the present specification may include isomers (compounds having the same number of atoms but having different structures), optical isomers, and isotopes unless otherwise limited. Moreover, only one kind or a plurality of kinds of the isomers and the isotopes may be included.

In addition, in the notation of a group (atomic group) in the present invention, in a case where the group is noted without specifying whether it is substituted or unsubstituted, the group includes both a group having no substituent and a group having a substituent within a range not interfering with the effect of the present invention. For example, a “hydrocarbon group” includes not only a hydrocarbon group having no substituent (an unsubstituted hydrocarbon group) but also a hydrocarbon group having a substituent (a substituted hydrocarbon group). This also applies to each of compounds.

In the present specification, “ppm” means “parts-per-million (10⁻⁶)” and “ppb” means “parts-per-billion (10⁻⁹)”.

In addition, in the present specification, 1 A (angstrom) corresponds to 0.1 nm.

In the present specification, psi means a pound-force per square inch; 1 psi=6894.76 Pa.

[Treatment Liquid]

The treatment liquid of an embodiment of the present invention (hereinafter also simply referred to as a “treatment liquid”) is a treatment liquid for a semiconductor substrate, and includes a component A having two or more onium structures, and water. In addition, the pH of the treatment liquid at 25° C. is 6.0 to 13.5.

The present inventors have found that in a case where the treatment liquid includes a component A having two or more onium structures, and has a pH of 6.0 to 13.5, the corrosion prevention performance for a metal-containing layer of a semiconductor substrate (hereinafter also described as “the effect of the present invention”) is improved, thereby completing the present invention.

Although detailed mechanism by which the effect of the present invention is obtained with such a treatment liquid is unclear, the present inventors have presumed that the component A acts on the metal-containing layer whose surface is charged on the anion side in contact with the treatment liquid, and thus, the surface of the metal-containing layer is provided with corrosion prevention properties.

Hereinafter, each component included in the treatment liquid will be described.

[Component A]

The treatment liquid includes a component A having two or more onium structures in the molecule.

Here, the onium structure included in the component A means a cationic structure in which a proton (H⁺) is added to a monatomic hydride. Examples of the onium structure include an ammonium structure in which the central atom is N, a phosphonium structure in which the central atom is P, an arsonium structure in which the central atom is As, an oxonium structure in which the central atom is O, and a sulfonium structure in which the central atom is S.

The component A is not particularly limited as long as it is a compound having two or more onium structures in the molecule. The component A may be a salt consisting of a cation having two or more onium structures, and a counterion. In that case, the component A may be ionized in the treatment liquid.

As the onium structure contained in the component A, an ammonium structure, a phosphonium structure, or a sulfonium structure is preferable, the ammonium structure or the phosphonium structure is more preferable, and the ammonium structure is still more preferable.

The number of onium structures contained in the molecule of the component A is preferably 2 to 6, more preferably 2 to 4, still more preferably 2 or 3, and particularly preferably 2.

The component A preferably has a monovalent organic group bonded to the central atom of the onium structure and a linking group bonded to the central atoms of two or more onium structures.

Examples of the monovalent organic group include an aliphatic hydrocarbon group, an aromatic hydrocarbon group, and a group formed by combination of two or more of these groups. As the monovalent organic group, an alkyl group, an alkenyl group, a cycloalkyl group, an aryl group, or an aralkyl group is preferable.

The monovalent organic group preferably has 1 to 20 carbon atoms, more preferably has 1 to 14 carbon atoms, and still more preferably has 1 to 10 carbon atoms.

In a case where the component A has two or more of the organic groups, those organic groups may be the same as or different from each other.

Examples of the alkyl group include a methyl group, an ethyl group, a propyl group, a butyl group, a pentyl group, a hexyl group, a heptyl group, and an octyl group; and the methyl group, the ethyl group, the propyl group, or the butyl group is preferable, and the methyl group is more preferable.

As the alkenyl group, an alkenyl group having 2 to 10 carbon atoms is preferable, and an ethynyl group or a propyl group is more preferable.

As the cycloalkyl group, a cycloalkyl group having 3 to 10 carbon atoms is preferable, a cyclohexyl group or a cyclopentyl group is more preferable, and a cyclohexyl group is still more preferable.

As the aryl group, an aryl group having 6 to 14 carbon atoms is preferable, a phenyl group or a naphthyl group is more preferable, and the phenyl group is still more preferable.

As the aralkyl group, an aralkyl group having 7 to 14 carbon atoms is preferable, and a benzyl group is more preferable.

The monovalent organic group may further have a substituent. Examples of the substituent that can be introduced include a hydroxyl group, an amino group, a carboxyl group, a phosphoric acid group, an imino group, a thiol group, a sulfo group, and a nitro group.

As the linking group bonded to the central atoms of the two or more onium structures, a divalent linking group bonded to the central atoms of the two onium structures is preferable.

Examples of the divalent linking group include an aliphatic hydrocarbon group, an aromatic hydrocarbon group, and a group formed by combination of two or more of these groups. As the divalent linking group, an alkylene group, an alkenylene group, a cycloalkylene group, an arylene group, or a group formed by combination of two or more of these groups is preferable.

The divalent linking group may have —S—, —S(═O)₂—, —O—, —C(═O)—, and a group formed by a combination of two or more of these groups, instead of the methylene group (—CH₂—) constituting the divalent linking group. In addition, the divalent linking group may have a linking group in which the central atom (preferably a nitrogen atom) of the onium structure has two of the monovalent substituents, instead of the methylene group (—CH₂—) constituting the linking group.

The divalent linking group preferably has 1 to 30 carbon atoms, more preferably 2 to 20 carbon atoms, and still more preferably 2 to 12 carbon atoms.

As the alkylene group, an alkylene group having 1 to 10 carbon atoms is preferable. Among those, a methylene group, an ethylene group, a propylene group, a butylene group, a pentylene group, a hexylene group, a heptylene group, or an octylene group is more preferable, and the ethylene group or the pentylene group is still more preferable.

As the alkenylene group, an alkenylene group having 2 to 10 carbon atoms is preferable, an ethynylene group or a propynylene group is more preferable, and the propynylene group is still more preferable.

As the cycloalkylene group, a cycloalkylene group having 3 to 10 carbon atoms is preferable, a cyclohexylene group or a cyclopentylene group is more preferable, and the cyclohexylene group is still more preferable.

As the arylene group, an alkylene group having 6 to 14 carbon atoms is preferable, a phenylene group or a naphthylene group is more preferable, and the phenylene group is still more preferable.

As the group formed by combination of two or more selected from the alkylene group, the alkenylene group, the cycloalkylene group, and the arylene group, a dialkylphenyl group or a biphenyl group is preferable.

The linking group may further have a substituent. Examples of the substituent that can be introduced include a hydroxyl group, an amino group, a carboxyl group, a phosphoric acid group, an imino group, a thiol group, a sulfo group, and a nitro group.

In addition, in the component A, two or more linking groups bonded to one onium structure may be present. For example, in a case where the component A has two onium structures, the component A may have two or more divalent linking groups that link the two onium structures. In a case where the component A has two or more linking groups, the linking groups may be the same as or different from each other.

Examples of the counterion contained in the component A include a monovalent anion and a divalent anion.

More specific examples of the counterion include a nitrate ion, a sulfate ion, a halide ion (for example, a bromide ion, a chloride ion, a fluoride ion, and an iodide ion), a citrate ion, a phosphate ion, an oxalate ion, a phthalate ion, a maleate ion, a gluconate ion, a fumarate ion, a tartrate ion, a malate ion, a glycolate ion, a hydroxide ion, an acetate ion, a trifluoroacetate ion, a borate ion, a lactate ion, a thiocyanate ion, a cyanate ion, a sulfate ion, a silicate ion, a perhalide ion (for example, a perbromate ion, a perchlorate ion, and a periodate ion), a chromate ion, a p-toluenesulfonic acid ion, a benzenesulfonic acid ion, a methanesulfonate ion, a trifluoromethanesulfonate ion, an ethanesulfonic acid ion, a diglycolate ion, a 2,5-furandicarboxylate ion, a 2-tetrafluoroborate ion, a tetrafluoroborate ion, and a hexafluorophosphate ion.

Among those, the nitrate ion, the citrate ion, the phosphate ion, the oxalate ion, the phthalate ion, the maleate ion, the fumarate ion, the tartrate ion, the malate ion, the glycolate ion, the hydroxide ion, the acetate ion, the trifluoroacetate ion, the lactate ion, the sulfate ion, the silicate ion, the p-toluenesulfonate ion, the benzenesulfonate ion, the methanesulfonate ion, the trifluoromethane sulfonate ion, the ethanesulfonate ion, the diglycolate ion, the 2,5-furandicarboxylate ion, the 2-tetracarboxylic acid ion, the borate ion, the tetrafluoroborate ion, or the hexafluorophosphate ion is preferable, the hydroxide ion, the sulfate ion, or the phosphate ion is more preferable, and the hydroxide ion is still more preferable.

The component A is preferably a compound represented by General Formula (I) or (II), and more preferably the compound represented by General Formula (I).

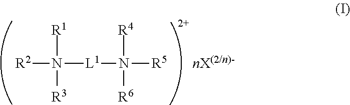

In General Formula (I), R¹ to R⁶ each independently represent a monovalent organic group. Two of R¹ to R⁶ may be bonded to each other. L¹ represents a divalent linking group. X^{(2/n)-} represents a (2/n)-valent counterion. n represents 1 or 2.

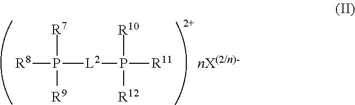

In General Formula (II), R⁷ to R¹² each independently represent a monovalent organic group. Two of R⁷ to R¹² may be bonded to each other. L² represents a divalent linking group. X^{(2/n)-} represents a (2/n)-valent counterion. n represents 1 or 2.

Furthermore, preferred aspects of the monovalent organic groups represented by R^{l} to R⁶ and R⁷ to R¹² in General Formulae (I) and (II) are the same as described earlier as the preferred aspects of the monovalent organic group bonded to the central atom of the onium structure having the component A.

In addition, preferred aspects of the divalent linking groups represented by L¹ and L², the linking group formed by the mutual bonding of two of R¹ to R⁶, and the linking group formed by the mutual bonding of two of R⁷ to R¹² in General Formulae (I) and (II) are the same as described earlier as the preferred aspects of the divalent linking group bonded to the central atom of the two onium structures having the component A.

X^{(2/n)-} in General Formulae (I) and (II) represents a monovalent or divalent counterion. That is, in a case where n is 1, X^{(2/n)-} represents a divalent counterion, and in a case where n is 2, X^{(2/n)-} represents a monovalent counterion.

Preferred aspects of the monovalent or divalent counterion represented by X^{(2/n)-} in General Formulae (I) and (II) are the same as described earlier as the preferred aspects of the counterion contained in the component A.

Hereinafter, cations (A-1) to (A-32) are shown as specific examples of cations having two onium structures constituting the component A.

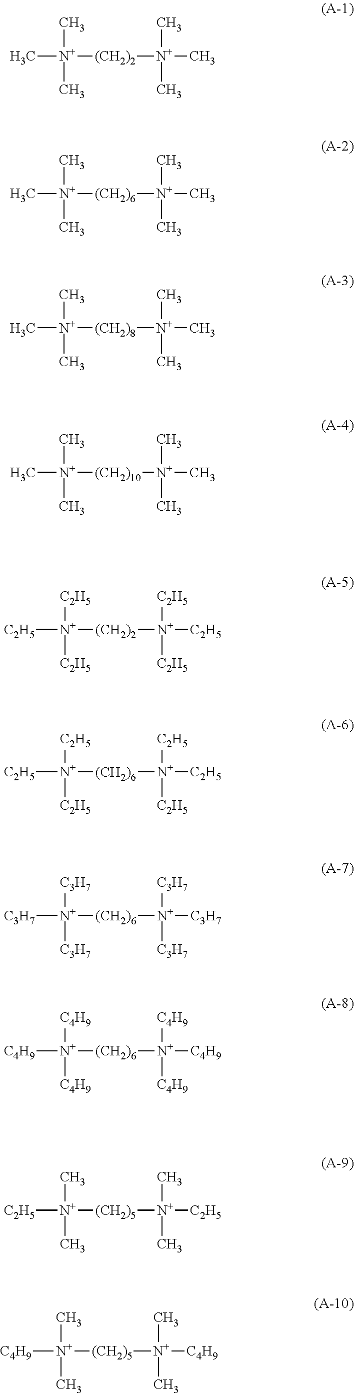

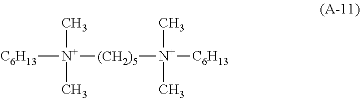

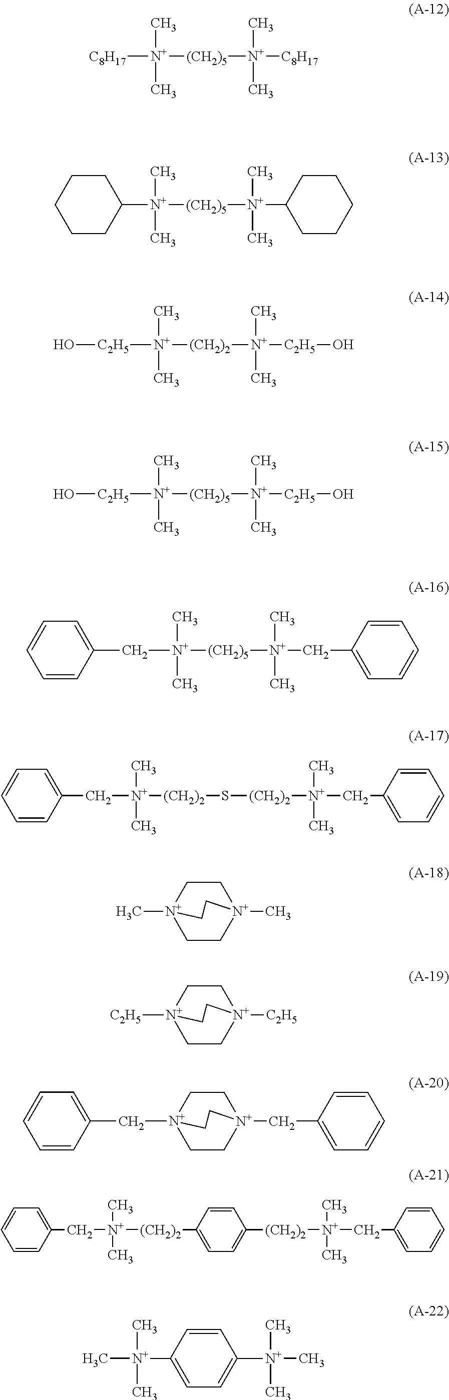

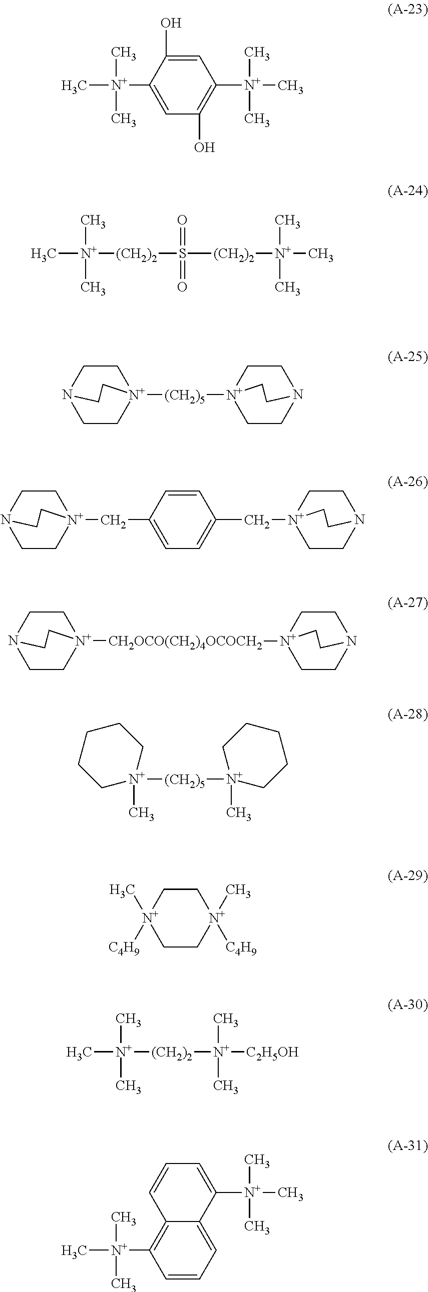

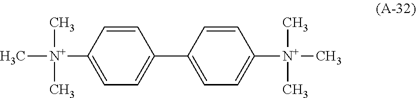

In addition, specific examples of a cation having two onium structures constituting the component A also include cations (A-X1) to (A-X32) corresponding to cations in which “N⁺” in the cations (A-1) to (A-32) is substituted with “P⁺”. For example, the cations (A-X1) and (A-X2) are each represented by the following chemical formulae.

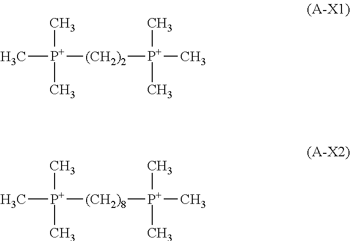

The component A preferably has a cation selected from the group consisting of the cations (A-1) to (A-32) and (A-X1) to (A-X32), and more preferably has a cation selected from the group consisting of the cations (A-1) to (A-15), (A-18), (A-19), (A-22), (A-23), (A-29) to (A-32), (A-X1) to (A-X15), (A-X18), (A-X19), (A-X22), (A-X23), and (A-X29) to (A-X32).

Among those, as the component A, the compounds having the cations (A-1) to (A-15) and (A-X1) to (A-X15) are still more preferable, and the compounds having the cations (A-1) to (A-10), and (A-X1) to (A-X10) are particularly preferable.

As the component A, a commercially available compound may be used, or a compound synthesized according to a known method may be used. Examples of the method for synthesizing the component A include a method for synthesizing the component A by a substitution reaction in which ammonia or various amines act as a nucleophile.

The component A is preferably used in a treatment liquid in the form of a salt consisting of a cation having two or more onium structures, and a counterion.

The component A preferably has a low molecular weight. More specifically, the molecular weight of the component A is preferably 700 or less, more preferably 500 or less, and still more preferably 400 or less. The lower limit is not particularly limited, but is preferably 120 or more.

In addition, the component A preferably has 50 or less carbon atoms, more preferably has 40 or less carbon atoms, and still more preferably has 30 or less carbon atoms. The lower limit is not particularly limited, but is preferably 6 or more.

The component A may be used alone or in combination of two or more kinds thereof.

From the viewpoint that the effect of the present invention is more excellent, the content of the component A is preferably 0.0001% by mass or more, more preferably 0.01% by mass or more, still more preferably 0.5% by mass or more, and particularly preferably 0.8% by mass or more with respect to the total mass of the treatment liquid.

The upper limit value of the content of the component A is not particularly limited, but from the viewpoint that polishing flaw suppressing properties in a case where the treatment liquid is a polishing liquid is more excellent, and/or the residue removal performance in a case where the treatment liquid is an etchant is more excellent, the upper limit value is preferably 20% by mass or less, more preferably 10% by mass or less, still more preferably 8% by mass or less, and particularly preferably 5% by mass or less with respect to the total mass of the treatment liquid.

[Water]

The treatment liquid preferably includes water as a solvent.

The type of water used for the treatment liquid is not particularly limited as long as it does not adversely affect a semiconductor substrate, and distilled water, deionized water, and pure water (ultrapure water) can be used. Pure water is preferable from the viewpoint that it includes almost no impurities and has less influence on a semiconductor substrate in a step of manufacturing the semiconductor substrate.

The content of water in the treatment liquid may be a balance other than the component A and optional components which will be described later. The content of water, is, for example, preferably 1% by mass or more, more preferably 30% by mass or more, still more preferably 60% by mass or more, and particularly preferably 85% by mass or more with respect to the total mass of the treatment liquid. The upper limit is not particularly limited, but is preferably 99% by mass or less, and more preferably 95% by mass or less with respect to the total mass of the treatment liquid.

In addition, in a case where the treatment liquid contains an organic solvent, the content of water in the treatment liquid is preferably 1% by mass or more, more preferably 10% by mass or more, and still more preferably 20% by mass or more with respect to the total mass of the treatment liquid. The upper limit is not particularly limited, but is preferably 50% by mass or less, more preferably 40% by mass or less, and still more preferably 30% by mass or less with respect to the total mass of the treatment liquid.

[Optional Components]

The treatment liquid may include other optional components, in addition to the above-mentioned components. Examples of the optional components include an organic acid, an organic alkali, an anticorrosive agent, a surfactant, colloidal silica, a chelating agent whose coordinating group is a nitrogen-containing group (hereinafter also referred to as a “specific chelating agent”), an oxidizing agent, an organic solvent, and various additives.

The treatment liquid preferably includes at least one selected from the group consisting of the organic acid, the organic alkali, the anticorrosive agent, the surfactant, colloidal silica, the specific chelating agent, the oxidizing agent, and the organic solvent, and more preferably includes the organic acid or the organic alkali.

Hereinafter, the optional components will be described.

<Organic Acid>

The treatment liquid preferably includes an organic acid from the viewpoint that the removal performance of the metal-containing substance is improved.

An organic acid is an organic compound that has an acidic functional group and is acidic (with a pH of less than 7.0) in an aqueous solution. Examples of the acidic functional group include a carboxyl group, a phosphonic acid group, a sulfo group, a phenolic hydroxyl group, and a mercapto group.

Furthermore, in the present specification, the compound functioning as an anionic surfactant, which will be described later, and the compound included in the anionic polymer compound are not included in the organic acid.

The organic acid is not particularly limited, but examples thereof include a carboxylic acid having a carboxyl group in the molecule (organic carboxylic acid), a phosphonic acid having a phosphonic acid group in the molecule (organic phosphonic acid), and a sulfonic acid having a sulfo group in the molecule (organic sulfonic acid), and the carboxylic acid or the phosphonic acid is preferable.

The number of acidic functional groups contained in the organic acid is not particularly limited, but is preferably 1 to 4, and more preferably 1 to 3.

In addition, the organic acid is preferably a compound having a function of chelating with a metal included in the residue from the viewpoint that the cleaning performance is excellent, and the organic acid is more preferably a compound having two or more functional groups (coordinating groups) that coordinate with a metal ion in the molecule. Examples of the coordinating group include the functional groups, and the carboxylic acid group or the phosphonic acid group is preferable.

(Carboxylic Acid)

The carboxylic acid may be a monocarboxylic acid having one carboxyl group or a polycarboxylic acid having 2 or more carboxyl groups. The polycarboxylic acid having 2 or more (more preferably 2 to 4, and still more preferably 2 or 3) carboxyl groups is preferable from the viewpoint that the cleaning performance is more excellent.

Examples of the carboxylic acid include an aminopolycarboxylic acid, an amino acid, a hydroxycarboxylic acid, and an aliphatic carboxylic acid.

-Aminopolycarboxylic Acid-

The aminopolycarboxylic acid is a compound having one or more amino groups and two or more carboxy groups as the coordinating group in the molecule.

Examples of the aminopolycarboxylic acid include aspartic acid, glutamate, butylenediaminetetraacetic acid, diethylenetriaminepentaacetic acid (DTPA), ethylenediaminetetrapropionic acid, triethylenetetraaminehexaacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid (CyDTA), ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanoltetraacetic acid, (hydroxyethyl)ethylenediaminetriacetic acid, and iminodiacetic acid (IDA).

Among those, DTPA, EDTA, CyDTA, or IDA is preferable.

-Amino Acid-

The amino acid is a compound that has one carboxyl group and one or more amino groups in the molecule.

Examples of the amino acid include glycine, serine, α-alanine (2-aminopropionic acid), β-alanine (3-aminopropionic acid), lysine, leucine, isoleucine, cystine, cysteine, methionine, ethionine, threonine, tryptophan, tyrosine, valine, histidine, a histidine derivative, asparagine, glutamine, arginine, proline, phenylalanine, the compounds described in paragraphs [0021] to [0023] of JP2016-086094A, and salts thereof. Incidentally, as the histidine derivative, the compounds described in JP2015-165561A and JP2015-165562A, the contents of which are incorporated herein by reference, can be used. In addition, examples of the salt include alkali metal salts such as a sodium salt and a potassium salt, an ammonium salt, a carbonate, and acetate.

Among those, histidine, the histidine derivative, or the sulfur-containing amino acid containing a sulfur atom is preferable, and histidine or the sulfur-containing amino acid is more preferable. Examples of the sulfur-containing amino acid include cystine, cysteine, ethionine, and methionine, and cystine or cysteine is preferable.

-Hydroxycarboxylic Acid-

A hydroxycarboxylic acid is a compound having one or more hydroxyl groups and one or more amino groups in the molecule.

Examples of the hydroxycarboxylic acid include malic acid, citric acid, glycolic acid, gluconic acid, heptonic acid, tartaric acid, and lactic acid; and gluconic acid, glycolic acid, malic acid, tartaric acid, or citric acid is preferable, and gluconic acid or citric acid is more preferable.

-Aliphatic Carboxylic Acid-

Examples of the aliphatic carboxylic acid include oxalic acid, malonic acid, succinic acid, glutaric acid, adipic acid, pimelic acid, sebacic acid, and maleic acid.

Examples of carboxylic acids other than the aminopolycarboxylic acid, the amino acid, the hydroxycarboxylic acid, and the aliphatic carboxylic acid include monocarboxylic acids.

Examples of the monocarboxylic acid include lower (1 to 4 carbon atoms) aliphatic monocarboxylic acids such as formic acid, acetic acid, propionic acid, and butyric acid.

As the carboxylic acid, an amino acid, a hydroxycarboxylic acid, or an aliphatic carboxylic acid is preferable, cystine, cysteine, histidine, gluconic acid, glycolic acid, malic acid, tartaric acid, citric acid, or adipic acid is more preferable, and cysteine, gluconic acid, citric acid, or adipic acid is still more preferable.

The carboxylic acid may be used alone or in combination of two or more kinds thereof.

The content of the carboxylic acid in the treatment liquid is not particularly limited. In a case where the treatment liquid is used as the polishing liquid, the content is preferably 0.01% to 3% by mass, and more preferably 0.03% to 0.5% by mass with respect to the total mass of the treatment liquid.

(Phosphonic Acid)

The phosphonic acid may be a monophosphonic acid having one phosphonic acid or a polyphosphonic acid having two or more phosphonic acid groups.

As the polyphosphonic acid, the compounds represented by General Formulae [1] to [3] described in paragraphs [0013] to [0023] of WO2013/162020A, the compounds described in paragraphs [0026] to [0036] of WO2018/020878A, or the compounds ((co)polymers) described in paragraphs [0031] to [0046] of WO2018/030006A, the contents of which can be incorporated herein by reference, can be used.

Examples of the polyphosphonic acid include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethylenephosphonic acid), triethylenetetraminehexa(methylenephosphonic acid), and triethylenetetraminehexa(ethylenephosphonic acid), and HEDPO is preferable.

The number of phosphonic acid groups contained in the phosphonic acid is preferably 2 to 5, more preferably 2 to 4, and still more preferably 2 or 3.

In addition, the phosphonic acid preferably has 12 or less carbon atoms, more preferably has 10 or less carbon atoms, and still more preferably 8 or less carbon atoms. The lower limit is not particularly limited, and is preferably 1 or more.

The phosphonic acid may be used alone or in combination of two or more kinds thereof.

The content of the phosphonic acid in the treatment liquid is not particularly limited, but is preferably 2% by mass or less, and more preferably 1% by mass or less with respect to the total mass of the treatment liquid. The lower limit is not particularly limited, but is preferably 0.01% by mass or more, and more preferably 0.05% by mass or more with respect to the total mass of the treatment liquid.

The organic acid preferably has a low molecular weight. More specifically, the molecular weight of the organic acid is preferably 600 or less, more preferably 450 or less, and still more preferably 300 or less. The lower limit is not particularly limited, but is preferably 85 or more.

In addition, the organic acid preferably has 15 or less carbon atoms, more preferably has 12 or less carbon atoms, and still more preferably 8 or less carbon atoms. The lower limit is not particularly limited, but is preferably 2 or more.

The organic acid may be used alone or in combination of two or more kinds thereof.

The content of the organic acid in the treatment liquid is not particularly limited, but is preferably 10% by mass or less, and more preferably 5% by mass or less with respect to the total mass of the treatment liquid. The lower limit is not particularly limited, but is preferably 0.01% by mass or more, and more preferably 0.03% by mass or more with respect to the total mass of the treatment liquid.

<Organic Alkali>

The treatment liquid may include an organic alkali.

The organic alkali is an organic compound having an alkaline (basic) functional group and exhibiting alkalinity (with a pH of more than 7.0) in an aqueous solution.

Examples of the organic alkali include an amine compound and a quaternary ammonium compound. Incidentally, in the present specification, the quaternary ammonium compound is intended to be a compound having one quaternary ammonium structure.

(Amine Compound)

The amine compound is a compound having an amino group in the molecule, in which the compound is not included in the heteroaromatic compound which will be described later.

Examples of the amine compound include a primary aliphatic amine having a primary amino group (—NH₂) in the molecule, a secondary aliphatic amine having a secondary amino group (>NH) in the molecule, and a tertiary aliphatic amine having a tertiary amino group (>N—) in the molecule.

The amine compound is a compound having a group selected from a primary amino group, a secondary amino group, and a tertiary amino group (which may be hereinafter collectively referred to as “primary to tertiary amino groups”) in the molecule, or a salt thereof, and is not particularly limited as long as it is a compound having no heterocyclic ring including a nitrogen atom.

Examples of the salt of the amine compound include a salt of an inorganic acid in which at least one non-metal selected from the group consisting of Cl, S, N, and P is bonded to hydrogen, and the salt is preferably a hydrochloride, a sulfate, or a nitrate.

Examples of the amine compound include an amino alcohol, an alicyclic amine compound, and an aliphatic monoamine compound, and an aliphatic polyamine compound other than the amino alcohol and the alicyclic amine.

-Amino Alcohol-

The amino alcohol is a compound having at least one hydroxylalkyl group in the molecule among the amine compounds, and is also referred to as an alkanolamine. The amino alcohol may have any of primary to tertiary amino groups, but preferably has the primary amino group.

Examples of the amino alcohol include monoethanolamine (MEA), diethanolamine (DEA), triethanolamine (TEA), diethylene glycolamine (DEGA), trishydroxymethylaminomethane (Tris), and 2-amino-2-methyl-1-propanol (AMP), 2-amino-2-methyl-1,3-dipropanol (AMPD), 2-amino-2-ethyl-1,3-dipropanol (AEPD), 2-(methylamino)-2-methyl-1-propanol (N-MAMP), 2-(aminoethoxy)ethanol (AEE), and 2-(2-aminoethylamino)ethanol (AAE).

Among those, AMP, N-MAMP, MEA, DEA, or TEA is preferable, and AMP, MEA, or TEA is more preferable.

The amino alcohol may be used alone or in combination of two or more kinds thereof.

From the viewpoint that the effect of the present invention is more excellent, the content of the amino alcohol is preferably 0.01% by mass or more, more preferably 0.3% by mass or more, and still more preferably 0.8% by mass or more with respect to the total mass of the treatment liquid. From the viewpoint that the effect of the present invention is more excellent, the upper limit value of the content of the amino alcohol is not particularly limited, but is preferably 20% by mass or less, more preferably 8% by mass or less, and still more preferably 4% by mass or less with respect to the total mass of the treatment liquid.

In addition, in a case where the treatment liquid includes an amino alcohol, a mass ratio of the content of the component A to the content of amino alcohol (the content of component A/the content of amino alcohol) is preferably 0.01 to 20, and from the viewpoint that the effect of the present invention is more excellent, the mass ratio is more preferably 0.08 to 3, and still more preferably 0.12 to 0.8.

-Alicyclic Amine Compound-

The alicyclic amine compound is not particularly limited as long as it is a compound having a non-aromatic heterocyclic ring in which at least one of the atoms constituting the ring is a nitrogen atom.

Examples of the alicyclic amine compound include a piperazine compound and a cyclic amidine compound.

The piperazine compound is a compound having a hetero-6-membered ring (piperazine ring) in which the opposite —CH— group of a cyclohexane ring is substituted with a nitrogen atom.

The piperazine compound may have a substituent on the piperazine ring. Examples of such a substituent include a hydroxy group, an alkyl group having 1 to 4 carbon atoms, which may have a hydroxy group, and an aryl group having 6 to 10 carbon atoms.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), N-(2-aminoethyl)piperazine (AEP), 1,4-bis(2-hydroxyethyl) piperazine (BHEP), 1,4-bis(2-aminoethyl) piperazine (BAEP), and 1,4-bis(3-aminopropyl) piperazine (BAPP).

The cyclic amidine compound is a compound having a heterocyclic ring including an amidine structure (>N—C═N—) in the ring.

The number of ring members of the heterocyclic ring contained in the cyclic amidine compound is not particularly limited, but is preferably 5 or 6, and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine.

Other examples of the alicyclic amine compound include a compound having a non-aromatic, hetero-5-membered ring such as 1,3-dimethyl-2-imidazolidinone and imidazolidinethione, and a compound having a 7-membered ring, including a nitrogen atom.

-Aliphatic Monoamine Compound-

The aliphatic monoamine compound other than the amino alcohol and the alicyclic amine is not particularly limited as long as it is a compound not included in the primary amine, and examples thereof include methylamine, ethylamine, propylamine, dimethylamine, diethylamine, n-butylamine, 3-methoxypropylamine, tert-butylamine, n-hexylamine, cyclohexylamine, n-octylamine, 2-ethylhexylamine, and 4-(2-aminoethyl) morpholine (AEM).

-Aliphatic Polyamine Compound-

Examples of the aliphatic polyamine compound other than amino alcohols and alicyclic amines include alkylenediamines such as ethylenediamine (EDA), 1,3-propanediamine (PDA), 1,2-propanediamine, 1,3-butanediamine, and 1,4-butanediamine, and polyalkylpolyamines such as diethylenetriamine (DETA), triethylenetetramine (TETA), bis(aminopropyl)ethylenediamine (BAPEDA), and tetraethylenepentamine.

In addition, as the amine compound, the compounds described in paragraphs [0034] to [0056] of WO2013/162020A, the contents which are incorporated herein by reference, can be used.

The amine compound preferably has one or more hydrophilic groups in addition to one primary to tertiary amino group. Examples of the hydrophilic group include primary to tertiary amino groups and a hydroxyl group. Examples of the amine compound having one or more hydrophilic groups in addition to one primary to tertiary amino group include an amino alcohol, an aliphatic polyamine compound, and a compound having two or more hydrophilic groups among alicyclic amine compounds, and the amino alcohol is preferable.

The upper limit of the total number of the hydrophilic groups contained in the amine compound is not particularly limited, but is preferably 4 or less, and more preferably 3 or less.

The number of primary to tertiary amino groups contained in the amine compound is not particularly limited, but is preferably 1 to 4, and more preferably 1 to 3.

In addition, the molecular weight of the amine compound is not particularly limited, but is preferably 200 or less, and more preferably 150 or less. The lower limit is not particularly limited, but is preferably 60 or more.

In a case where the treatment liquid includes an amine compound, the content of the amine compound is preferably 0.01% by mass or more, more preferably 0.3% by mass or more, and still more preferably 0.8% by mass or more with respect to the total mass of the treatment liquid. The upper limit of the content of the amine compound is preferably 20% by mass or less, more preferably 8% by mass or less, and still more preferably 4% by mass or less with respect to the total mass of the treatment liquid.

In addition, in a case where the treatment liquid includes an amine compound, the mass ratio of the content of the component A to the content of the amine compound (the content of component A/the content of the amine compound) is preferably 0.01 to 20, more preferably 0.08 to 3, and still more preferably and 0.12 to 0.8 from the viewpoint that the effect of the present invention is more excellent.

(Quaternary Ammonium Compound)

The treatment liquid may include a quaternary ammonium compound which is a compound having one quaternary ammonium cation or a salt thereof in the molecule.

The quaternary ammonium compound is not particularly limited as long as it is a compound having one quaternary ammonium cation in which a nitrogen atom is substituted with four hydrocarbon groups (preferably an alkyl group), or a salt thereof.

Examples of the quaternary ammonium compound include a quaternary ammonium hydroxide, a quaternary ammonium fluoride, a quaternary ammonium bromide, a quaternary ammonium iodide, a quaternary ammonium acetate, and a quaternary ammonium carbonate.

As the quaternary ammonium compound, a quaternary ammonium hydroxide represented by Formula (1) is preferable.

(R¹³)₄N⁺OH⁻ (1)

In the formula, R¹³ represents an alkyl group which may have a hydroxy group or a phenyl group as a substituent. Four of R¹³'s may be the same as or different from each other.

As the alkyl group represented by R¹³, an alkyl group having 1 to 4 carbon atoms is preferable, and a methyl group or an ethyl group is more preferable.

As the alkyl group which may have a hydroxy group or a phenyl group, represented by R¹³, a methyl group, an ethyl group, a propyl group, a butyl group, a 2-hydroxyethyl group, or a benzyl group is preferable, the methyl group, the ethyl group, the propyl group, the butyl group, or the 2-hydroxyethyl group is more preferable, and the methyl group, the ethyl group, or the 2-hydroxyethyl group is still more preferable.

Examples of the quaternary ammonium compound include tetramethylammonium hydroxide (TMAH), trimethylethylammonium hydroxide (TMEAH), diethyldimethylammonium hydroxide (DEDMAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-Hydroxyethyl)dimethylammonium hydroxide, tri(2-hydroxyethyl)methylammonium hydroxide, tetra(2-hydroxyethyl) ammonium hydroxide, benzyltrimethylammonium hydroxide (BTMAH), and cetyltrimethylammonium hydroxide.

As the quaternary ammonium compound other than the specific examples, for example, the compound described in paragraph [0021] of JP2018-107353A, the contents of which are incorporated herein by reference, can be used.

The quaternary ammonium compound may be used alone or in combination of two or more kinds thereof.

The content of the quaternary ammonium compound is preferably 0.001% to 20% by mass, and more preferably 0.01% to 10% by mass with respect to the total mass of the treatment liquid.

The treatment liquid may include an organic alkali other than the amine compound and the quaternary ammonium compound. Examples of such another organic alkali include a compound selected from the group consisting of amine oxide, nitro, nitroso, oxime, ketoxime, aldoxime, lactam, isocyanide, and urea, which are not included in the component A.

The organic alkali may be used alone or in combination of two or more kinds thereof.

The content of the organic alkali is preferably 0.001% to 20% by mass, and more preferably 0.01% to 10% by mass with respect to the total mass of the treatment liquid.

<Anticorrosive Agent>

The treatment liquid preferably includes an anticorrosive agent (corrosion inhibitor) from the viewpoint that the effect of the present invention is more excellent.

The anticorrosive agent used in the treatment liquid is not particularly limited, and examples thereof include a heteroaromatic compound, a hydroxylamine compound, an ascorbic acid compound, a catechol compound, a hydrazide compound, a reducing sulfur compound, and an anionic polymer compound.

(Heteroaromatic Compound)

The treatment liquid may include a heteroaromatic compound as the anticorrosive agent.

The heteroaromatic compound is a compound having a heteroaromatic ring structure in the molecule. The heteroaromatic compound is not particularly limited as long as it is a compound having a heteroaromatic ring, and examples thereof include a nitrogen-containing, heteroaromatic compound having a heteroaromatic ring (nitrogen-containing, heteroaromatic ring) in which at least one of the atoms constituting the ring is a nitrogen atom.

The nitrogen-containing, heteroaromatic compound is not particularly limited, but examples thereof include an azole compound, a pyridine compound, a pyrazine compound, and a pyrimidine compound.

The azole compound is a compound having a hetero-5-membered ring that includes at least one nitrogen atom and has aromaticity. The number of nitrogen atoms included in the hetero-5-membered ring of the azole compound is not particularly limited, and is preferably 2 to 4, more preferably 3 or 4.

In addition, all of these azole compounds may have substituents on the hetero-5-membered ring. Examples of such a substituent include a hydroxy group, a carboxy group, a mercapto group, an amino group, an alkyl group having 1 to 4 carbon atoms, which may have an amino group, and a 2-imidazolyl group.

Examples of the azole compound include an imidazole compound, a pyrazole compound, a thiazole compound, a triazole compound, and a tetrazole compound.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, benzoimidazole, 2-aminobenzoimidazole, and adenine.

Examples of the pyrazole compound include pyrazole, 4-pyrazolecarboxylic acid, 1-methylpyrazole, 3-methylpyrazole, 3-amino-5-hydroxypyrazole, 3-amino-5-methylpyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, and 5-methyl-1H-benzotriazole.

Examples of the tetrazole compound include 1H-tetrazole (1,2,3,4-tetrazole), 5-methyl-1,2,3,4-tetrazole, 5-amino-1,2,3,4-tetrazole (5-aminotetrazole), 1,5-pentamethylenetetrazole, 1-phenyl-5-mercaptotetrazole, and 1-(2-dimethylaminoethyl)-5-mercaptotetrazole.

As the azole compound, the tetrazole compound, the triazole compound, the imidazole compound, or the pyrazole compound is preferable, and 5-aminotetrazole, benzotriazole, 5-methyl-1H-benzotriazole, or 3-aminopyrazole is more preferable.

The pyridine compound is a compound having a hetero-6-membered ring (pyridine ring) that includes one nitrogen atom and has aromaticity.

Examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having aromaticity and having a hetero-6-membered ring (pyrazine ring) including two nitrogen atoms located at the para positions, and the pyrimidine compound is a compound having aromaticity and having a hetero-6-membered ring (pyrimidine ring) including two nitrogen atoms located at the meta positions.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine.

Examples of the pyrimidine compound include pyrimidine, 2-methylpyrimidine, 2-aminopyrimidine, and 4,6-dimethylpyrimidine, and 2-aminopyrimidine is preferable.

As the heteroaromatic compound, the azole compound or the pyrazine compound is preferable, the azole compound is more preferable, and at least one selected from the group consisting of the tetrazole compound, the triazole compound, the imidazole compound, and the pyrazole compound is still more preferable.

The heteroaromatic compound may be used alone or in combination of two or more kinds thereof.

In a case where the treatment liquid includes a heteroaromatic compound, the content of the heteroaromatic compound in the treatment liquid is not particularly limited, but is preferably 0.00001% to 5% by mass, and more preferably 0.00005% to 1% by mass with respect to the total mass of the treatment liquid.

(Hydroxylamine Compound)

The hydroxylamine compound means at least one selected from the group consisting of hydroxylamine (NH₂OH), a hydroxylamine derivative, and salts thereof. In addition, the hydroxylamine derivative means a compound in which at least one organic group is substituted with hydroxylamine (NH₂OH).

The salt of the hydroxylamine or the hydroxylamine derivative may be an inorganic acid salt or an organic acid salt of the hydroxylamine or the hydroxylamine derivative. As the salt of the hydroxylamine or the hydroxylamine derivative, a salt of an inorganic acid in which at least one non-metal selected from the group consisting of Cl, S, N, and P is bonded to hydrogen is preferable, and a hydrochloride, a sulfate, or a nitrate is more preferable.

Examples of the hydroxylamine compound include a compound represented by Formula (2) or a salt thereof.

(R¹⁴)₂N—OH (2)

In Formula (2), R¹⁴ represents a hydrogen atom or an organic group. Two of R¹⁴'s may be the same as or different from each other.

As the organic group represented by R¹⁴, an alkyl group having 1 to 6 carbon atoms is preferable. The alkyl group having 1 to 6 carbon atoms may be linear, branched, or cyclic.

In addition, it is preferable that at least one of the two of R¹⁴'s is an organic group (more preferably an alkyl group having 1 to 6 carbon atoms).

As the alkyl group having 1 to 6 carbon atoms, an ethyl group or an n-propyl group is preferable, and the ethyl group is more preferable.

Examples of the hydroxylamine compound include hydroxylamine, O-methylhydroxylamine, O-ethylhydroxylamine, N-methylhydroxylamine, N,N-dimethylhydroxylamine, N,O-dimethylhydroxylamine, N-ethylhydroxylamine, N,N-diethylhydroxylamine (DEHA), N,O-diethylhydroxylamine, O,N,N-trimethylhydroxylamine, N,N-dicarboxyethylhydroxylamine and N,N-disulfoethylhydroxylamine; and hydroxylamine or DEHA is preferable.

(Ascorbic Acid Compound)

The ascorbic acid compound means at least one selected from the group consisting of ascorbic acid, an ascorbic acid derivative, and salts thereof.

Examples of the ascorbic acid derivative include an ascorbic acid phosphoric acid ester and an ascorbic acid sulfuric acid ester.

As the ascorbic acid compound, the ascorbic acid, the ascorbic acid phosphoric acid ester, or the ascorbic acid sulfuric acid ester is preferable, and the ascorbic acid is more preferable.

(Catechol Compound)

The catechol compound means at least one selected from the group consisting of pyrocatechol (benzene-1,2-diol) and a catechol derivative.

The catechol derivative means a compound in which at least one substituent is substituted in pyrocatechol. As the substituent contained in the catechol derivative, a hydroxy group, a carboxy group, a carboxylic acid ester group, a sulfo group, a sulfonic acid ester group, an alkyl group (preferably having 1 to 6 carbon atoms, and more preferably having 1 to 4 carbon atoms), and an aryl group (preferably a phenyl group). The carboxy group and the sulfo group contained as a substituent in the catechol derivative may be a salt of a cation. In addition, the alkyl group and the aryl group contained as a substituent in the catechol derivative may further have a substituent.

Examples of the catechol compound include pyrocatechol, 4-tert-butylcatechol, pyrogallol, gallate, methyl gallate, 1,2,4-benzenetriol, and Tyrone.

(Hydrazide Compound)

The hydrazide compound means a compound having a hydroxy group of an acid substituted with a hydrazino group (—NH—NH₂), and a derivative thereof (a compound having at least one substituent substituted in a hydrazino group).

The hydrazide compound may have two or more hydrazino groups.

Examples of the hydrazide compound include carboxylic acid hydrazide and sulfonic acid hydrazide, and carbohydrazide (CHZ) is preferable.

(Reducing Sulfur Compound)

The reducing sulfur compound is a compound that has reducing properties and includes a sulfur atom. Examples of the reducing sulfur compound include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among those, a compound having an SH group (mercapto compound) is preferable, and 1-thioglycerol, sodium 3-mercapto-1-propanesulfonate, 2-mercaptoethanol, 3-mercapto-1-propanol, or thioglycolic acid is more preferable.

(Polymer Compound)

The treatment liquid may include a polymer compound as the anticorrosive agent.

As the polymer compound, an anionic polymer compound is preferable. The anionic polymer compound is a compound that has an anionic group and has a weight-average molecular weight of 1,000 or more. In addition, the anionic polymer compound does not include a compound that functions as an anionic surfactant which will be described later.

Examples of the anionic polymer compound include a polymer having a monomer having a carboxyl group as a basic constitutional unit and a salt thereof, and a copolymer including them. More specific examples of the anionic polymer compound include a polyacrylic acid and a salt thereof, and a copolymer including them; a polymethacrylic acid and a salt thereof, and a copolymer including them; a polyamic acid and a salt thereof, and a copolymer including them; and polycarboxylic acids such as polymaleic acid, polyitaconic acid, polyfumaric acid, poly(p-styrenecarboxylic acid), and polyglioxylic acid, and a salt thereof, and a copolymer including them.

Among those, at least one selected from the group consisting of a copolymer including polyacrylic acid, polymethacrylic acid, polyacrylic acid and polymethacrylic acid, and a salt thereof is preferably included.

Incidentally, the anionic polymer compound may be ionized in the treatment liquid.

A weight-average molecular weight of the polymer compound is preferably 1,000 to 100,000, more preferably 2,000 to 50,000, and still more preferably 5,000 to 50,000.

The weight-average molecular weight of the polymer compound is a polystyrene-equivalent value obtained by a gel permeation chromatography (GPC) method. The GPC method is based on a method using HLC-8020GPC (manufactured by Tosoh Corporation), and using TSKgel SuperHZM-H, TSKgel SuperHZ4000, and TSKgel SuperHZ2000 (manufactured by Tosoh Corporation, 4.6 mm ID × 15 cm) as columns and tetrahydrofuran (THF) as an eluent.

The polymer compound may be used alone or in combination of two or more kinds thereof.

A content of the polymer compound is preferably 0.01% by mass or more, and more preferably 0.10% by mass or more with respect to the total mass of the treatment liquid. The upper limit value of the content of the polymer compound is preferably 10% by mass or less, and more preferably 5% by mass or less with respect to the total mass of the treatment liquid.

(Clathrate Compound)

The treatment liquid may include a clathrate compound as the anticorrosive agent. In the present specification, the “clathrate compound” means a so-called host compound having a space in which a compound such as an organic compound and fine solid particles can be incorporated into the molecule.

Examples of the clathrate compound include cyclodextrin. Examples of the cyclodextrin include α-cyclodextrin, β-cyclodextrin and γ-cyclodextrin, and γ-cyclodextrin is preferable.

Furthermore, as the clathrate compound, the compound described in JP2008-210990A, the contents of which are incorporated herein by reference, can be used.

The treatment liquid may include another anticorrosive agent other than the respective components.

Examples of such another anticorrosive agent include sugars such as fructose, glucose and ribose, polyols such as ethylene glycol, propylene glycol, and glycerin, polyvinylpyrrolidone, cyanuric acid, barbituric acid and a derivative thereof, glucuronic acid, squaric acid, α-ketoic acid, adenosine and a derivative thereof, a purine compound and a derivative thereof, phenanthroline, resorcinol, nicotine amide and a derivative thereof, flavonol and a derivative thereof, anthocyanin and a derivative thereof, and a combination thereof.

The treatment liquid preferably includes a heteroaromatic compound, a hydroxylamine compound, an anionic polymer compound, or a clathrate compound, and more preferably includes the heteroaromatic compound or the hydroxylamine compound, as the anticorrosive agent.

The anticorrosive agent may be used alone or in combination of two or more kinds thereof.

In a case where the treatment liquid includes an anticorrosive agent, the content of the anticorrosive agent is not particularly limited, but is preferably 0.00001% to 10% by mass, and more preferably 0.0005% to 3% by mass with respect to the total mass of the treatment liquid.

Furthermore, as these anticorrosive agents, commercially available ones may be used, or those synthesized according to a known method may be used.

<Surfactant>

It is preferable that the treatment liquid includes a surfactant from the viewpoint that the effect of the present invention is more excellent.

The surfactant is not particularly limited as long as it is a compound having a hydrophilic group and a hydrophobic group (parent oil group) in the molecule, and examples thereof include an anionic surfactant, a cationic surfactant, a nonionic surfactant, and an amphoteric surfactant.

The surfactant often has a hydrophobic group selected from an aliphatic hydrocarbon group, an aromatic hydrocarbon group, and a combination thereof. The hydrophobic group contained in the surfactant is not particularly limited, but in a case where the hydrophobic group includes an aromatic hydrocarbon group, it has preferably 6 or more carbon atoms, and more preferably has 10 or more carbon atoms. In a case where the hydrophobic group does not include an aromatic hydrocarbon group and is composed only of an aliphatic hydrocarbon group, it preferably has 10 or more carbon atoms, more preferably has 12 or more carbon atoms, and still more preferably has 16 or more carbon atoms. The upper limit of the number of carbon atoms of the hydrophobic group is not particularly limited, but is preferably 20 or less, and more preferably 18 or less.

(Anionic Surfactant)

Examples of the anionic surfactant included in the treatment liquid include phosphoric acid ester-based surfactants having a phosphoric acid ester group, phosphonic acid-based surfactants having a phosphoric acid group, sulfonic acid-based surfactants having a sulfo group, carboxylic acid-based surfactants having a carboxy group, and sulfuric acid ester-based surfactants having a sulfuric acid ester group, respectively, as a hydrophilic group (acid group).

-Phosphoric Acid Ester-Based Surfactant-

Examples of the phosphoric acid ester-based surfactants include a phosphoric acid ester (an alkyl ether phosphoric acid ester and an aryl ether phosphoric acid ester), a polyoxyalkylene ether phosphoric acid ester (a polyoxyalkylene alkyl ether phosphoric acid ester and a polyoxyalkylene aryl ether phosphoric acid ester), and salts thereof. The phosphoric acid ester and the polyoxyalkylene ether phosphoric acid ester often include both a monoester and a diester, but such the monoester and diester can each be used alone.

Examples of the salt of the phosphoric acid ester-based surfactant include a sodium salt, a potassium salt, an ammonium salt, and an organic amine salt.

The monovalent alkyl group contained in the phosphoric acid ester and the polyoxyalkylene ether phosphoric acid ester is not particularly limited, but is preferably an alkyl group having 2 to 24 carbon atoms, more preferably an alkyl group having 6 to 18 carbon atoms, and still more preferably an alkyl group having 12 to 18 carbon atoms.

The monovalent aryl group contained in the phosphoric acid ester and the polyoxyalkylene ether phosphoric acid ester is not particularly limited, but is preferably an aryl group having 6 to 14 carbon atoms, which may have an alkyl group, more preferably a phenyl group or naphthyl group which may have an alkyl group, and still more preferably a phenyl group which may have an alkyl group.

The divalent alkylene group contained in the polyoxyalkylene ether phosphoric acid ester is not particularly limited, but is preferably an alkylene group having 2 to 6 carbon atoms, and more preferably an ethylene group or a 1,2-propanediyl group. In addition, the number of repetitions of the oxyalkylene group in the polyoxyalkylene ether phosphoric acid ester is preferably 1 to 12, and more preferably 3 to 10.

As the phosphoric acid ester-based surfactant, an octyl phosphoric acid ester, a lauryl phosphoric acid ester, a tridecyl phosphoric acid ester, a myristyl phosphoric acid ester, a cetyl phosphoric acid ester, a stearyl phosphoric acid ester, a polyoxyethylene octyl ether phosphoric acid ester, a polyoxyethylene lauryl ether phosphoric acid ester, a polyoxyethylene tridecyl ether phosphoric acid ester, or a polyoxyethylene dimethylphenyl ether phosphoric acid ester is preferable.

As the phosphoric acid ester-based surfactant, the compounds described in paragraphs [0012] to [0019] of JP2011-040502A, the contents of which are incorporated herein by reference, can also be used.

-Phosphonic Acid-Based Surfactant-

Examples of the phosphonic acid-based surfactant include alkylphosphonic acid, polyvinylphosphonic acid, and the aminomethylphosphonic acid described in JP2012-057108A.

-Sulfonic Acid-Based Surfactant-

Examples of the sulfonic acid-based surfactant include alkyl sulfonic acid, alkyl benzene sulfonic acid, alkyl naphthalene sulfonic acid, alkyl diphenyl ether disulfonic acid, alkyl methyl taurine, sulfosuccinic acid diester, polyoxyalkylene alkyl ether sulfonic acid, and salts thereof.

The monovalent alkyl group contained in the sulfonic acid-based surfactant is not particularly limited, but is preferably an alkyl group having 10 or more carbon atoms, and more preferably an alkyl group having 12 or more carbon atoms. The upper limit is not particularly limited, but is preferably 24 or less.

Moreover, the divalent alkylene group contained in the polyoxyalkylene alkyl ether sulfonic acid is not particularly limited, but is preferably an ethylene group or a 1,2-propanediyl group. In addition, the number of repetitions of the oxyalkylene group in the polyoxyalkylene alkyl ether sulfonic acid is preferably 1 to 12, and more preferably 1 to 6.

Specific examples of the sulfonic acid-based surfactant include hexane sulfonic acid, octane sulfonic acid, decane sulfonic acid, dodecane sulfonic acid, toluene sulfonic acid, cumene sulfonic acid, octylbenzene sulfonic acid, dodecylbenzenesulfonic acid (DBSA), dinitrobenzene sulfonic acid (DNBSA), and lauryldodecylphenyl ether disulfonic acid (LDPEDSA).

-Carboxylic Acid-Based Surfactant-

Examples of the carboxylic acid-based surfactant include an alkylcarboxylic acid, an alkylbenzenecarboxylic acid, a polyoxyalkylene alkyl ether carboxylic acid, and salts thereof.

The monovalent alkyl group contained in the above-mentioned carboxylic acid-based surfactant is not particularly limited, but is preferably an alkyl group having 7 to 25 carbon atoms, and more preferably an alkyl group having 11 to 17 carbon atoms.

The divalent alkylene group contained in the polyoxyalkylene alkyl ether carboxylic acid is not particularly limited, but is preferably an ethylene group or a 1,2-propanediyl group. In addition, the number of repetitions of the oxyalkylene group in the polyoxyalkylene alkyl ether carboxylic acid is preferably 1 to 12, and more preferably 1 to 6.

Specific examples of the carboxylic acid-based surfactant include lauric acid, myristic acid, palmitic acid, stearic acid, polyoxyethylene lauryl ether acetic acid, and polyoxyethylene tridecyl ether acetic acid.

-Sulfuric Acid Ester-Based Surfactant-

Examples of the sulfuric acid ester-based surfactant include a sulfuric acid ester (alkyl ether sulfuric acid ester), a polyoxyalkylene ether sulfuric acid ester, and salts thereof.

The monovalent alkyl group contained in the sulfuric acid ester and the polyoxyalkylene ether sulfuric acid ester is not particularly limited, but is preferably an alkyl group having 2 to 24 carbon atoms, and more preferably an alkyl group having 6 to 18 carbon atoms.

The divalent alkylene group contained in the polyoxyalkylene ether sulfuric acid ester is not particularly limited, but is preferably an ethylene group or a 1,2-propanediyl group. In addition, the number of repetitions of the oxyalkylene group in the polyoxyalkylene ether sulfuric acid ester is preferably 1 to 12, and more preferably 1 to 6.

Specific examples of the sulfuric acid ester-based surfactant include a lauryl sulfuric acid ester, a myristyl sulfuric acid ester, and a polyoxyethylene lauryl ether sulfuric acid ester.

As the anionic surfactant, the phosphoric acid ester-based surfactant, the sulfonic acid-based surfactant, the phosphonic acid-based surfactant, or the carboxylic acid-based surfactant is preferable, and the phosphoric acid ester-based surfactant is more preferable.

These anionic surfactant may be used alone or in combination of two or more kinds thereof.

In a case where the treatment liquid includes an anionic surfactant, the content of the anionic surfactant is preferably 0.0001% to 5.0% by mass, more preferably 0.0005% to 0.5% by mass, still more preferably 0.001% to 0.1% by mass, and particularly preferably 0.005% to 0.05% by mass with respect to the total mass of the treatment liquid from the viewpoint that the effect of the present invention is more excellent.

Furthermore, as these anionic surfactants, commercially available ones may be used.

(Cationic Surfactant)

Examples of the cationic surfactant include primary to tertiary alkylamine salts (for example, monostearylammonium chloride, distearylammonium chloride, and tristearylammonium chloride), and modified aliphatic polyamines (for example, polyethylene polyamine).

(Nonionic Surfactant)

Examples of the nonionic surfactant include polyoxyalkylene alkyl ethers (for example, polyoxyethylene stearyl ether and polyoxyethylene lauryl ether), polyoxyalkylene alkenyl ethers (for example, polyoxyethylene oleyl ether), polyoxyethylene alkylphenyl ethers (for example, polyoxyethylene nonylphenyl ether), polyoxyalkylene glycol (for example, polyoxypropylene polyoxyethylene glycol), polyoxyalkylene monoalkyates (monoalkyl fatty acid ester polyoxyalkylene) (for example, polyoxyethylene monoalkylates such as polyoxyethylene monostearate and polyoxyethylene monooleate), polyoxyalkylene dialkylates (dialkyl fatty acid ester polyoxyalkylene) (for example, polyoxyethylene dialkylates such as polyoxyethylene distearate and polyoxyethylene diolate), bispolyoxyalkylene alkylamides (for example, bispolyoxyethylene stearylamide), a sorbitan fatty acid ester, a polyoxyethylene sorbitan fatty acid ester, a polyoxyethylene alkylamine, a glycerin fatty acid ester, an oxyethylene oxypropylene block copolymer, an acetylene glycol-based surfactant, and an acetylene-based polyoxyethylene oxide.

As the nonionic surfactant, the polyoxyalkylene alkyl ether is preferable, and the polyoxyethylene stearyl ether or the polyoxyethylene lauryl ether is more preferable.

(Amphoteric Surfactant)

Examples of the amphoteric surfactant include carboxybetaine (for example, alkyl-N,N-dimethylaminoacetic acid betaine and alkyl-N,N-dihydroxyethylaminoacetic acid betaine), sulfobetaine (for example, alkyl-N,N-dimethylsulfoethyleneammonium betaine), and imidazolinium betaine (for example, 2-alkyl-N-carboxymethyl-N-hydroxyethyl imidazolinium betaine).

As the surfactant, the compounds described in paragraphs [0092] to [0096] of JP2015-158662A, paragraphs [0045] and [0046] of JP2012-151273A, and paragraphs [0014] to [0020] of JP2009-147389A, the contents of which are incorporated herein by reference, can also be used.

The surfactant may be used alone or in combination of two or more kinds thereof. In a case where the treatment liquid includes a surfactant, the content of the surfactant is preferably 0.0001% to 5.0% by mass, more preferably 0.0005% to 0.5% by mass, still more preferably 0.001% to 0.1% by mass, and particularly preferably 0.005% to 0.05% by mass with respect to the total mass of the treatment liquid from the viewpoint that the effect of the present invention is more excellent.

In a case where the treatment liquid includes a surfactant, a mass ratio of the content of the component A to the content of the surfactant (the content of the component A/the content of the surfactant) is preferably 0.1 to 2,000, more preferably 0.3 to 1,000, still more preferably 1 to 500, particularly preferably 5 to 300, and most preferably 10 to 100 from the viewpoint that the effect of the present invention is more excellent.

<Colloidal Silica (Abrasive Grains)>

In a case where the treatment liquid is used as a polishing liquid which will be described later, it is preferable that the treatment liquid includes colloidal silica (silica colloidal particles). The colloidal silica functions as abrasive grains for polishing an object to be polished.

In another aspect, in a case where the treatment liquid is used as the polishing liquid, the treatment liquid includes abrasive grains. Examples of the abrasive grains include inorganic abrasive grains such as silica, alumina, zirconia, ceria, titania, germania, and silicon carbide; and organic abrasive grains such as polystyrene, polyacryl, and polyvinyl chloride. Among those, the silica particles are preferable as the abrasive grains from the viewpoint that the dispersion stability in the treatment liquid is excellent and the number of polishing flaws (scratches) generated by CMP is small.

The silica particles are not particularly limited, and examples thereof include precipitated silica, fumed silica, and colloidal silica. Among those, the colloidal silica is more preferable.

The polishing liquid is preferably a slurry.

An average primary particle diameter of the colloidal silica is preferably 60 nm or less, more preferably 40 nm or less, and still more preferably 20 nm or less from the viewpoint that generation of defects on a surface to be polished can be further suppressed. The lower limit value of the average primary particle diameter of the colloidal silica is preferably 1 nm or more, and more preferably 3 nm or more from the viewpoint that the aggregation of the colloidal silica is suppressed and the temporal stability of the polishing liquid is thus improved.

An average primary particle diameter is obtained by measuring particle diameters (equivalent circle diameters) of any 1,000 primary particles selected from an image captured using a transmission electron microscope TEM2010 (pressurization voltage: 200 kV) manufactured by JEOL Ltd., and arithmetically averaging the values. Incidentally, the equivalent circle diameter is a diameter of a circle assuming a true circle having the same projected area as a projected area of a particle at the time of observation.

It should be noted that in a case where a commercially available product is used as the colloidal silica, a catalog value is preferentially adopted as the average primary particle diameter of the colloidal silica.

An average aspect ratio of the colloidal silica is preferably 1.5 to 2.0, more preferably 1.55 to 1.95, and still more preferably 1.6 to 1.9 from the viewpoint where a polishing power is improved.

The average aspect ratio of the colloidal silica is obtained by measuring a major diameter and a minor diameter for every arbitrary 100 particles observed with the above-mentioned transmission electron microscope to calculate aspect ratios (major diameter/minor diameter) of the respective particles, and arithmetically averaging the aspect ratios of the 100 particles. Incidentally, the major diameter of a particle means a length of the particle in a major axis direction, and the minor diameter of a particle means a length of the particle in a direction orthogonal to the major axis direction of the particle.

It should be noted that in a case where a commercially available product is used as the colloidal silica, a catalog value is preferentially adopted as the average aspect ratio of the colloidal silica.

A degree of association of the colloidal silica is preferably 1 to 3 from the viewpoint that the polishing speed is further increased.

In the present specification, the degree of association is determined by an equation: Degree of association=Average secondary particle diameter/Average primary particle diameter. An average secondary particle diameter corresponds to an average particle diameter (equivalent circle diameter) of secondary particles in an aggregated state, and can be determined by the same method as for the average primary particle diameter.

It should be noted that in a case where a commercially available product is used as the colloidal silica, a catalog value is preferentially adopted as the degree of association of the colloidal silica.

The colloidal silica may have a surface modifying group (a sulfonic acid group, a phosphonic acid group, and/or a carboxylic acid group, and the like) on the surface.

Incidentally, the group may be ionized in the polishing liquid.

A method for obtaining colloidal silica having a surface modifying group is not particularly limited, and examples thereof include the method described in JP2010-269985A.

As the colloidal silica, a commercially available product may be used, and examples thereof include PL1, PL3, PL7, PL10H, PL1D, PL07D, PL2D, and PL3D (all of which are product names, manufactured by Fuso Chemical Co., Ltd.).

The colloidal silica may be used alone or in combination of two or more kinds thereof.

The content of the colloidal silica is preferably 20.0% by mass or less, more preferably 10.0% by mass or less, and still more preferably 5.0% by mass or less with respect to the total mass of the treatment liquid. The lower limit value is preferably 0.1% by mass or more, and more preferably 1.0% by mass or more.

A suitable range of the content of an abrasive grains in the polishing liquid in a case where the treatment liquid includes the abrasive grains is the same as the suitable range of the content of the colloidal silica described above.

<Specific Chelating Agent>

The treatment liquid may include a specific chelating agent in which a coordinating group has a nitrogen-containing group. The specific chelating agent has two or more nitrogen-containing groups as a coordination group that coordinates with metal ions in one molecule. Examples of the nitrogen-containing group which is a coordination group include an amino group.

Examples of the specific chelating agent include a biguanide compound which is a compound having a biguanide group or a salt thereof. The number of biguanide groups contained in the biguanide compound is not particularly limited, and the biguanide compound may have a plurality of biguanide groups.

Examples of the biguanide compound include the compounds described in paragraphs [0034] of JP2017-504190A, the contents of which are incorporated herein by reference.

As the compounds having a biguanide group, ethylene dibiguanide, propylene dibiguanide, tetramethylene dibiguanide, pentamethylene dibiguanide, hexamethylene dibiguanide, heptamethylene dibiguanide, octamethylene dibiguanide,
1,1′-hexamethylenebis(5-(p-chlorophenyl)biguanide)(chlorhexidine),
2-(benzyloxymethyl)pentane-1,5-bis(5-hexylbiguanide),
2-(phenylthiomethyl)pentane-1,5-bis(5-phenetylbiguanide),
3-(phenylthio)hexane-1,6-bis(5-hexylbiguanide),
3-(phenylthio)hexane-1,6-bis(5-cyclohexylbiguanide),
3-(benzylthio)hexane-1,6-bis(5-hexylbiguanide), or
3-(benzylthio)hexane-1,6-bis(5-cyclohexylbiguanide) is preferable, and chlorhexidine is more preferable.

As the salt of the compound having a biguanide group, hydrochloride, acetate or gluconate is preferable, and gluconate is more preferable.

As the specific chelating agent, chlorhexidine gluconate (CHG) is preferable.

The specific chelating agent may be used alone or in combination of two or more kinds thereof.

In a case where the treatment liquid includes a specific chelating agent, the content of the specific chelating agent is not particularly limited, but is preferably 0.01% to 10% by mass, and more preferably 0.05% to 5% by mass with respect to the total mass of the treatment liquid.

<Oxidizing Agent>

The treatment liquid may include an oxidizing agent.

Examples of the oxidizing agent include hydrogen peroxide, peroxide, nitric acid and a salt thereof, iodic acid and a salt thereof, periodic acid and a salt thereof, hypochlorous acid and a salt thereof, chloric acid and a salt thereof, chloric acid and a salt thereof, perchloric acid and a salt thereof, persulfuric acid and a salt thereof, permanganic acid and a salt thereof, permanganic acid and a salt thereof, ozone water, a silver (II) salt, and an iron (III) salt.

As the oxidizing agent included in the treatment liquid, hydrogen peroxide, or periodic acid or a salt thereof is preferable. Among those, in a case where the treatment liquid is used as the polishing liquid, it is more preferable that the treatment liquid includes hydrogen peroxide.

The oxidizing agent may be used alone or in combination of two or more kinds thereof.

In a case where the treatment liquid includes an oxidizing agent, the content of the oxidizing agent is preferably 0.001% to 1% by mass, and more preferably 0.005% to 0.3% by mass with respect to the total mass of the treatment liquid.

<Organic Solvent>

The treatment liquid may include an organic solvent. In a case where the treatment liquid is used as a polishing liquid, the treatment liquid preferably includes an organic solvent.

The organic solvent is preferably a water-soluble organic solvent. The expression that the organic solvent is water-soluble means that water and the organic solvent at 25° C. can be mixed (dissolved) at any ratio.

Examples of the organic solvent include an alcohol-based solvent, a ketone-based solvent, an ester-based solvent, an ether-based solvent (for example, a glycol diether), a sulfone-based solvent, a sulfoxide-based solvent, a nitrile-based solvent, and an amide-based solvent. These solvents may be water-soluble.

As the organic solvent, one or more selected from the group consisting of the alcohol-based solvent, the ketone-based solvent, the ester-based solvent, and the ether-based solvent is preferable, and the ether-based solvent is more preferable.

Examples of the alcohol-based solvent include an alkanediol, an alkoxyalcohol, a saturated aliphatic monohydric alcohol, an unsaturated non-aromatic monohydric alcohol, and a low-molecular-weight alcohol containing a ring structure, and the alkoxyalcohol is preferable.

Examples of the alkoxyalcohol include 3-methoxy-3-methyl-1-butanol, 3-methoxy-1-butanol, 1-methoxy-2-butanol, and glycol monoether, and glycol monoether is preferable.

Examples of the glycol monoether include ethylene glycol monomethyl ether, ethylene glycol monoethyl ether, ethylene glycol mono-n-propyl ether, ethylene glycol monoisopropyl ether, ethylene glycol monobutyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Among those, diethylene glycol monoethyl ether is preferable.

Examples of the ketone-based solvent include acetone, propanone, cyclobutanone, cyclopentanone, cyclohexanone, diacetone alcohol, 2-butanone, 5-hexanedione, 1,4-cyclohexanedione, 3-hydroxyacetophenone, 1,3-cyclohexanedione, and cyclohexanone.

Examples of the ester-based solvent include glycol monoesters such as ethyl acetate (ethyl acetate), butyl acetate (butyl acetate), ethylene glycol monoacetate, and diethylene glycol monoacetate, and glycol monoether monoesters such as propylene glycol monomethyl ether acetate, ethylene glycol monomethyl ether acetate, propylene glycol monoethyl ether acetate, and ethylene glycol monoethyl ether acetate.

The organic solvent may be used alone or in combination of two or more kinds thereof.

In a case where the treatment liquid includes an organic solvent, the content of the organic solvent is preferably 0.1% to 99% by mass, and more preferably 1% to 90% by mass with respect to the total mass of the treatment liquid.

<Additive>

The treatment liquid may include an additive other than the components, as desired. Examples of such an additive include a pH adjuster, a chelating agent (excluding the organic acid and the specific chelating agent), and a fluorine compound.

(pH Adjuster)

The treatment liquid may include a pH adjuster to adjust and maintain the pH of the treatment liquid. Examples of the pH adjuster include a basic compound and an acidic compound other than the components.

Examples of the basic compound include a basic inorganic compound. In addition, in order to raise the pH of the treatment liquid, the organic alkali may be used.

Examples of the basic inorganic compound include an alkali metal hydroxide, an alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

As these basic compounds, commercially available ones may be used, or those appropriately synthesized by a known method may be used.

Examples of the acidic compound include an inorganic acid. In addition, in order to lower the pH of the treatment liquid, the organic acid and the anionic surfactant may be used.

Examples of the inorganic acid include hydrochloric acid, sulfuric acid, sulfurous acid, nitric acid, nitrite, phosphoric acid, boric acid, and hexafluorophosphoric acid. In addition, a salt of the inorganic acid may be used, and examples thereof include an ammonium salt of the inorganic acid, and more specifically, ammonium chloride, ammonium sulfate, ammonium sulfite, ammonium nitrate, ammonium nitrite, ammonium phosphate, ammonium borate, and ammonium hexafluoride phosphate.

As the inorganic acid, phosphoric acid or phosphate is preferable, and phosphoric acid is more preferable.

As the acidic compound, a salt of the acidic compound may be used as long as it is an acid or an acid ion (anion) in an aqueous solution.

As the acidic compound, commercially available ones may be used, or those appropriately synthesized by a known method may be used.

The pH adjuster may be used alone or in combination of two or more kinds thereof.

In a case where the treatment liquid includes a pH adjuster, the content of the pH adjuster is selected according to types and amounts of other components, and the pH of a target treatment liquid, but is preferably 0.01% to 3% by mass, and more preferably 0.05% to 1% by mass with respect to the total mass of the treatment liquid.

The treatment liquid may include another chelating agent other than an organic acid having a chelating function and the specific chelating agent. Examples of such another chelating agent include inorganic acid-based chelating agents such as a fused phosphoric acid and a salt thereof. Examples of the fused phosphoric acid and a salt thereof include pyrophosphoric acid and a salt thereof, metaphosphoric acid and a salt thereof, tripolyphosphoric acid and a salt thereof, and hexametaphosphoric acid and a salt thereof.

Examples of the fluorine compound include the compounds described in paragraphs [0013] to [0015] of JP2005-150236A, the contents of which are incorporated herein by reference.

The amount of such another chelating agent and the fluorine compound used is not particularly limited, and may be appropriately set as long as the effect of the present invention is not impaired.

The content of each of the components in the treatment liquid can be measured by a known method such as gas chromatography-mass spectrometry (GC-MS) or liquid chromatography-mass spectrometry (LC-MS), and ion-exchange chromatography (IC).

[Physical Properties of Treatment Liquid]

<pH>

The pH of the treatment liquid of the embodiment of the present invention is 6.0 to 13.5 at 25° C.

From the viewpoints that the effect of the present invention is more excellent, the residue removal performance in a case where the treatment liquid is an etchant is more excellent, and/or the polishing flaw suppressing properties in a case where the treatment liquid is a polishing liquid are more excellent, the pH of the treatment liquid is preferably 7.0 or more, and more preferably 8.0 or more at 25° C. In addition, from the viewpoints that the effect of the present invention is more excellent, the polishing flaw suppressing properties in a case where the treatment liquid is a polishing liquid are more excellent, and/or the residue removal performance in a case where the treatment liquid is an etchant is more excellent, the pH of the treatment liquid is preferably 12.5 or less, and more preferably 11.5 or less at 25° C.

The pH of the treatment liquid can be adjusted by using the pH adjuster and a component having a function of a pH adjuster, such as the organic acid, organic alkali, heteroaromatic compound, and anionic surfactant.

<Metal Content>

In the treatment liquid, the content of metals (metal elements of Fe, Co, Na, K, Cu, Mg, Mn, Li, Al, Cr, Ni, Zn, Sn, and Ag) included as impurities in the liquid (measured as an ion concentration) is preferably 5 ppm by mass or less, and more preferably 1 ppm by mass or less. The lower limit is not particularly limited, but is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples of the method include lining an inner wall of a pipe with a fluorine-based resin so that the metal component does not elute from the pipe during the production of the treatment liquid.

<Coarse Particles>

The treatment liquid may include other coarse particles other than abrasive grains such as colloidal silica, but the content of the coarse particles is preferably low. Here, the other coarse particles mean particles other than abrasive grains and having a diameter (particle diameter) of 0.4 μm or more in a case where the shape of the particles is regarded as a sphere.

As for the content of the coarse particles in the treatment liquid, the content of the particles having a particle diameter of 0.4 μm or more is preferably 1,000 or less, and more preferably 500 or less per mL of the treatment liquid. The lower limit is not particularly limited, and may be 0. In addition, it is more preferable that the content of particles having a particle diameter of 0.4 μm or more measured by the measuring method is no more than a detection limit.

The coarse particles included in the treatment liquid correspond to particles of dirt, dust, organic solids, inorganic solids, and the like included as impurities in raw materials, and particles of dirt, dust, and organic solids, and inorganic solids brought in as contaminants during the preparation of the treatment liquid, in which the particles are finally present as particles without being dissolved in the treatment liquid.

The content of the coarse particles present in the treatment liquid can be measured in the liquid phase using a commercially available measuring device in a light scattering type liquid particle measuring method using a laser as a light source.

Examples of a method for removing the coarse particles include a purifying treatment such as filtering which will be described later.

[Kit and Concentrate]

The treatment liquid may be used as a kit for preparing the treatment liquid by dividing the raw material into a plurality of parts. As a specific method using the treatment liquid as a kit, for example, an aspect in which in a case where the treatment liquid includes the component A, water, and a hydroxylamine compound, a liquid composition including water and the hydroxylamine compound is prepared as a first liquid, and a liquid composition including the component A is prepared as a second liquid may be mentioned.

The content of each component included in the first liquid and the second liquid provided in the kit is not particularly limited, but the content of each component in the treatment liquid prepared by mixing the first liquid and the second liquid is preferably an amount corresponding to the preferred amount described above.

The pH's of the first liquid and the second liquid provided in the kit are not particularly limited, and are preferably each adjusted so that a pH of the treatment liquid prepared by mixing the first liquid and the second liquid is within in the range of 6.0 to 13.5.

In addition, the treatment liquid may be prepared as a concentrated solution. In this case, it can be diluted with a diluent liquid at the time of use. That is, a kit may include the treatment liquid in the form of a concentrated solution and a diluent liquid.

[Production of Treatment Liquid]

The treatment liquid can be produced by a known method. Hereinafter, a method for producing the treatment liquid will be described in detail.

<Liquid Producing Step>

The method for producing a treatment liquid is not particularly limited, and for example, a treatment liquid can be produced by mixing the above-mentioned respective components. The order and/or the timing of mixing the above-mentioned respective components is not particularly limited, and for example, a production method in which the component A and any components are added sequentially or simultaneously to a container to which purified pure water has been incorporated, and then the mixture is stirred and mixed while a pH adjuster is added to the mixture to adjust the pH of the mixed solution, thereby performing the preparation, may be mentioned. In addition, in a case where water and the respective components are added to the container, they may be added all at once or dividedly a plurality of times.

A stirring device and a stirring method used for producing a treatment liquid are not particularly limited, and a known device as a stirrer or a disperser may be used. Examples of the stirrer include an industrial mixer, a portable stirrer, a mechanical stirrer, and a magnetic stirrer. Examples of the disperser include an industrial disperser, a homogenizer, an ultrasonic disperser, and bead mills.

The mixing of the respective components in the liquid producing step for the treatment liquid, and a purifying treatment which will be described later and the storage of the produced treatment liquid are preferably performed at 40° C. or lower, and more preferably at 30° C. or lower. In addition, the lower limit value of the storage temperature is preferably 5° C. or higher, more preferably 10° C. or higher. By producing, treating, and/or storing the treatment liquid in the temperature range, stable performance can be maintained for a long period of time.

(Purifying Treatment)

It is preferable to subject any one or more of the raw materials for preparing the treatment liquid to a purifying treatment in advance. The purifying treatment is not particularly limited, and examples thereof include known methods such as distillation, ion exchange, and filtration.

The degree of purification is not particularly limited, but it is preferable to perform the purification until a purity of the raw material is 99% by mass or more, and it is more preferable to perform the purification until the purity of the raw material is 99.9% by mass or more.

Specific examples of the method for the purifying treatment include a method of passing a raw material through an ion exchange resin or a reverse osmosis membrane (RO membrane), distillation of a raw material, and filtering which will be described later.

As the purifying treatment, a plurality of the above-mentioned purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purifying treatment may be carried out a plurality of times.

(Filtering)

A filter used for filtering is not particularly limited as long as it is the one that has been used for filtration in the related art. Examples thereof include a filter consisting of a fluorine-based resin such as polytetrafluoroethylene (PTFE) and a tetrafluoroethylene-perfluoroalkyl vinyl ether copolymer (PFA), a polyamide-based resin such as nylon, and a polyolefin resin (including a high-density polyolefin and an ultrahigh-molecular-weight polyolefin) such as polyethylene and polypropylene (PP). Among these materials, a material selected from the group consisting of the polyethylene, the polypropylene (including a high-density polypropylene), the fluorine-based resin (including PTFE and PFA), and the polyamide-based resin (including nylon) is preferable, and among these, the filter with the fluorine-based resin is more preferable. By performing filtering of the raw materials using a filter formed with these materials, high-polarity foreign matters which are likely to cause defects can be more effectively removed.

A critical surface tension of the filter is preferably 70 to 95 mN/m, and more preferably 75 to 85 mN/m. Further, the value of the critical surface tension of the filter is a nominal value of a manufacturer. By using a filter having a critical surface tension in the range, high-polarity foreign matters which are likely to cause defects can be more effectively removed.

The pore diameter of the filter is preferably 2 to 20 nm, and more preferably 2 to 15 nm. By adjusting the pore diameter of the filter to be in the range, it is possible to reliably remove fine foreign matters such as impurities and aggregates included in the raw materials while suppressing clogging in filtering. With regard to the pore diameters herein, reference can be made to nominal values of filter manufacturers.

Filtering may be performed only once or twice or more. In a case where filtering is performed twice or more, the filters used may be the same as or different from each other.

Moreover, the filtering is preferably performed at room temperature (25° C.) or lower, more preferably performed at 23° C. or lower, and still more preferably performed at 20° C. or lower. In addition, the temperature is preferably 0° C. or higher, more preferably 5° C. or higher, and still more preferably 10° C. or higher. By performing filtering in the temperature range, the amount of particulate foreign matter and impurities dissolved in the raw material can be reduced, and the foreign matter and impurities can be efficiently removed.

(Container)

The treatment liquid (including aspects of the kit or a diluent which will be described later) can be filled in any container and stored, transported, and used as long as there is no problem in corrosiveness.

In semiconductor applications, as the container, a container that has a high degree of cleanliness inside the container, and suppresses elution of impurities from an inner wall of an accommodating portion of the container into each liquid is preferable. Examples of such a container include various containers commercially available as a container for a semiconductor treatment liquid, such as “Clean Bottle” series manufactured by AICELLO MILIM CHEMICAL Co., Ltd. and “Pure Bottle” manufactured by Kodama Plastics Co., Ltd., but the container is not limited thereto.

In addition, as the container for accommodating the treatment liquid, a container in which a liquid contact portion with each liquid, such as an inner wall of the accommodating portion, is formed from a fluorine-based resin (perfluororesin) or a metal which has been subjected to rust prevention and metal elution prevention treatments is preferable.

The inner wall of the container is preferably formed from one or more resins selected from the group consisting of a polyethylene resin, a polypropylene resin, and a polyethylene-polypropylene resin, other resins, and a metal which has been rust prevention and metal elution preventing treatments, such as stainless steel, Hastelloy, Inconel, and Monel.

As such other resins, a fluorine-based resin (perfluororesin) is preferable. In this manner, by using a container having an inner wall formed of a fluorine-based resin, occurrence of a problem of elution of ethylene or propylene oligomers can be suppressed, as compared with a container having an inner wall formed of a polyethylene resin, a polypropylene resin, or a polyethylene-polypropylene resin.

Specific examples of such a container having an inner wall which is a fluorine-based resin include a FluoroPurePFA composite drum manufactured by Entegris Inc. In addition, the containers described on page 4 of JP1991-502677A (JP-H03-502677A), page 3 of WO2004/016526A, and pages 9 and 16 of WO99/046309A can also be used.

Moreover, for the inner wall of the container, quartz and an electropolished metal material (that is, a completely electropolished metal material) are also preferably used, in addition to the above-mentioned fluorine-based resin.

The metal material used for producing the electropolished metal material is preferably a metal material which includes at least one selected from the group consisting of chromium and nickel, and has a total content of chromium and nickel of more than 25% by mass with respect to the total mass of the metal material, and examples thereof include stainless steel and a nickel-chromium alloy.

The total content of chromium and nickel in the metal material is more preferably 30% by mass or more with respect to the total mass of the metal material.

In addition, the upper limit value of the total content of Cr and Ni in the metal material is not particularly limited, but is preferably 90% by mass or less.

A method for electropolishing the metal material is not particularly limited, and electropolishing can be performed by a known method. For example, electropolishing can be performed by the methods described in paragraphs [0011] to [0014] of JP2015-227501A, and paragraphs [0036] to [0042] of JP2008-264929A.

The inside of these containers is preferably cleaned before the treatment liquid is filled. For the liquid used for the cleaning, the amount of the metal impurities in the liquid is preferably reduced. The treatment liquid may be bottled in a container such as a gallon bottle and a coated bottle after the production, and transported, and stored.

In order to prevent the change in the components in the treatment liquid during the storage, the inside of the container may be replaced with inert gas (nitrogen, argon, or the like) with a purity of 99.99995% by volume or more. In particular, a gas having a low moisture content is preferable. In addition, during the transportation and the storage, the temperature may be controlled to a normal temperature in the range of −20° C. to 20° C. to prevent deterioration.

(Clean Room)

It is preferable that handlings including production of the treatment liquid, opening and cleaning of a container, and filling of the treatment liquid, treatment analysis, and measurements are all performed in a clean room. It is preferable that the clean room satisfies 14644-1 clean room standards. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

<Diluting Step>

The above-mentioned treatment liquid may be subjected to a treatment of a semiconductor substrate after undergoing a diluting step of diluting with a diluent such as water.

A dilution ratio of the treatment liquid in the diluting step can be appropriately adjusted according to a type and a content of each component, and a semiconductor substrate as an object to be treated, but the ratio by volume of the dilution treatment liquid to the treatment liquid before dilution is preferably 10 to 10,000, more preferably 20 to 3,000, and still more preferably 50 to 1,000.

In addition, the treatment liquid is preferably diluted with water from the viewpoint that it has more excellent defect inhibition performance.

A change in a pH before and after dilution (a difference between the pH of the treatment liquid before dilution and the pH of the diluted treatment liquid) is preferably 1.0 or less, more preferably 0.8 or less, and still more preferably 0.5 or less.

In addition, the pH of the diluted solution is preferably more than 7.0, more preferably 7.5 or more, and still more preferably 8.0 or more at 25° C. The upper limit of the pH of the diluted treatment liquid is preferably 13.0 or less, more preferably 12.5 or less, and still more preferably 12.0 or less at 25° C.

A specific method for the diluting step of diluting the treatment liquid is not particularly limited, and may be performed according to the above-mentioned liquid producing step for the treatment liquid. The stirring device and the stirring method used in the diluting step are also not particularly limited, and the known stirring device mentioned in the liquid producing step for the treatment liquid may be used to perform the dilution.

It is preferable to subject the water used in the diluting step to a purification step in advance. In addition, it is preferable to subject the diluted treatment liquid obtained in the diluting step to a purifying treatment.

The purifying treatment is not particularly limited, and examples thereof include an ion component reducing treatment using an ion exchange resin or an RO membrane, and foreign matter removal using filtering, described as the above-mentioned purifying treatment for the treatment liquid, and it is preferable to carry out any one of these treatments.

[Use]

Next, a use of the treatment liquid will be described.

The treatment liquid can be used as a treatment liquid for a semiconductor substrate used in a semiconductor substrate manufacturing process. That is, the treatment liquid can be used in any step for manufacturing a semiconductor substrate.

Examples of the use of the treatment liquid include a cleaning liquid, a CMP slurry, an etchant, a pre-wet liquid, and a rinsing liquid.

The treatment liquid can be used as a cleaning liquid for a semiconductor substrate for removing adhering residues such as metal impurities or fine particles from a metal-containing layer of the semiconductor substrate.

The treatment liquid can be used as a CMP slurry supplied to a polishing pad in a CMP treatment in which a surface to be polished of an object to be polished is polished using the polishing pad.

The treatment liquid can be used as an etchant that dissolves and removes metal-containing substances on the semiconductor substrate.

The treatment liquid can be used as a pre-wet liquid to be applied on a substrate to improve the coatability of an actinic ray-sensitive or radiation-sensitive composition before the step of forming a resist film using the composition.

Examples of the use of the treatment liquid include a use as a rinsing liquid for rinsing the treatment liquid adhering to the semiconductor substrate.

The treatment liquid may be used in only one use or two or more of the uses.

[Method for Treating Semiconductor Substrate]

In a method for treating a semiconductor substrate using a treatment liquid (hereinafter also simply referred to as “the present treatment method”), the treatment liquid can be typically used in contact with a semiconductor substrate (hereinafter also referred to as an “object to be treated”) containing a metal-containing substance which is a material containing a metal. At this time, the object to be treated may contain a plurality of kinds of metal-containing substances.

[Object to Be Treated]

An object to be treated, which is an object to be treated using a treatment liquid, is not particularly limited as long as it has a metal-containing substance on the semiconductor substrate.

Furthermore, the expression “on the semiconductor substrate” in the present specification encompasses, for example, front and back surfaces, a side surface, and the inside of a groove of the semiconductor substrate. In addition, the metal-containing substance on the semiconductor substrate encompasses not only a case where the metal-containing substance is directly on a surface of the semiconductor substrate but also a case where the metal-containing substance is present on the semiconductor substrate via another layer.

The metal-containing substance is a material including a simple substance of a metal (metal atom) as a main component.

Examples of the metal included in the metal-containing substance include at least one metal M selected from the group consisting of copper (Cu), cobalt (Co), tungsten (W), titanium (Ti), tantalum (Ta), ruthenium (Ru), chromium (Cr), hafnium (Hf), osmium (Os), platinum (Pt), nickel (Ni), manganese (Mn), zirconium (Zr), molybdenum (Mo), lantern (La), and iridium (Ir).

The metal-containing substance only needs to be a substance containing a metal (metal atom), and examples thereof include a simple substance of the metal M, an alloy including the metal M, an oxide of the metal M, a nitride of the metal M, and an acid nitride of the metal M.

In addition, the metal-containing substance may be a mixture including two or more of these compounds.

Furthermore, the oxide, the nitride, and the oxynitride may be a composite oxide, a composite nitride, or a composite oxynitride, including a metal.

The content of the metal atom in the metal-containing substance is preferably 10% by mass or more, more preferably 30% by mass or more, and still more preferably 50% by mass or more with respect to the total mass of the metal-containing substance. The upper limit is 100% by mass since the metal-containing substance may be the metal itself.

A form of the metal-containing substance is not particularly limited, and may be, for example, any of a film-like (layered) form, a wiring line-like form, and a particle-like form.

The metal-containing substance may be arranged only on one main surface of the substrate, or may be arranged on both main surfaces. In addition, the metal-containing substance may be arranged on the whole main surface of the substrate, or may be arranged on a part of the main surface of the substrate.

The semiconductor substrate preferably has a metal M-containing substance including a metal M, more preferably has a metal-containing substance including at least one metal selected from the group consisting of Cu, Co, W, Ti, Ta, and Ru, and more preferably has a metal-containing substance including at least one metal selected from the group consisting of Cu, W, and Co.

More specific examples of the object to be treated include a substrate having a metal wire film, a barrier film, and an insulating film on a surface of a wafer constituting the semiconductor substrate.

Specific examples of the wafer constituting a semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

The silicon wafer may be an n-type silicon wafer in which a silicon wafer is doped with a pentavalent atom (for example, phosphorus (P), arsenic (As), and antimony (Sb)), and a p-type silicon wafer in which a silicon wafer is doped with a trivalent atom (for example, boron (B) and gallium (Ga)). The silicon of the silicon wafer may be, for example, amorphous silicon, single crystal silicon, polycrystalline silicon, or polysilicon.

Among those, the treatment liquid is useful for a wafer consisting of a silicon-based material, such as a silicon wafer, a silicon carbide wafer, and a resin-based wafer including silicon (glass epoxy wafers).

The semiconductor substrate may have an insulating film on the wafer.

Specific examples of the insulating film include a silicon oxide film (for example, a silicon dioxide (SiO₂) film, a tetraethyl orthosilicate (Si(OC₂H₅)₄) film (TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film).

The insulating film may be composed of a plurality of films. Examples of the insulating film composed of a plurality of films include an insulating film formed by combining a film including silicon oxide and a film including silicon oxycarbide.

Among those, the treatment liquid is useful as a treatment liquid for a semiconductor substrate having a low-dielectric-constant (Low-k) film as an insulating film.

Examples of the barrier film include a barrier film including one or more materials selected from the group consisting of tantalum (Ta), tantalum nitride (TaN), titanium nitride (TiN), tungsten nitride (TiW), tungsten (W), and tungsten nitride (WN).

The semiconductor substrate preferably has at least one selected from the group consisting of a film containing copper as a main component (copper-containing film), a film containing cobalt as a main component (Co-containing film), and a film containing tungsten as a main component (W-containing film), and more preferably contains a Co-containing film or a W-containing film.

Examples of the copper-containing film include a wiring line film consisting of only metallic copper (copper wiring line film), and a wiring line film consisting of an alloy of metallic copper and another metal (copper alloy wiring line film).

Specific examples of the copper alloy wiring line film include a wiring line film consisting of an alloy of one or more metals selected from A1, Ti, Cr, Mn, Ta, and W, and copper. More specific examples of the copper alloy wiring line film include a CuAl alloy wiring line film, a CuTi alloy wiring line film, a CuCr alloy wiring line film, a CuMn alloy wiring line film, a CuTa alloy wiring line film, and a CuW alloy wiring line film.

Examples of the Co-containing film include a metal film consisting of only metal cobalt (Co metal film), and a metal film consisting of an alloy composed of metallic cobalt and another metal (Co alloy metal film).

Specific examples of the Co alloy metal film include a metal film consisting of an alloy composed of one or more metals selected from Ti, Cr, Fe, Ni, Mo, Pd, Ta, and W, and cobalt. More specific examples of the Co alloy metal film include a CoTi alloy metal film, a CoCr alloy metal film, a CoFe alloy metal film, a CoNi alloy metal film, a CoMo alloy metal film, a CoPd alloy metal film, a CoTa alloy metal film, and a CoW alloy metal film.

Among the Co-containing films, the Co metal film is often used as the wiring line film, and the Co alloy metal film is often used as the barrier metal.

Examples of the W-containing film include a metal film consisting of only tungsten (W metal film) and a metal film consisting of an alloy made of tungsten and another metal (W alloy metal film).

Specific examples of the W alloy metal film include a WTi alloy metal film and a WCo alloy metal film.

The tungsten-containing film is often used as a barrier metal.

In addition to those mentioned above, the object to be treated may contain various layers and/or structures as desired. For example, the substrate may contain a metal wire, a gate electrode, a source electrode, a drain electrode, an insulating layer, a ferromagnetic layer, and/or a non-magnetic layer.

The substrate may contain exposed integrated circuit structures, for example, interconnect mechanism such as a metal wire and a dielectric material. Examples of the metal and the alloy used in the interconnect mechanism include aluminum, a copper-aluminum alloy, copper, titanium, tantalum, cobalt, silicon, titanium nitride, tantalum nitride, and tungsten. The substrate may contain layers of silicon oxide, silicon nitride, silicon carbide, and/or carbon-doped silicon oxide.

A method for producing the object to be treated is not particularly limited as long as it is a method usually performed in this field.

Examples of a method of forming the insulating film on a wafer constituting a semiconductor substrate include a method in which a wafer constituting a semiconductor substrate is subjected to a heat treatment in the presence of an oxygen gas to form a silicon oxide film, and then a gas of silane and ammonia is introduced thereto to form a silicon nitride film by a chemical vapor deposition (CVD) method.

Examples of a method for forming the metal-containing layer on a wafer constituting a semiconductor substrate include a method in which a circuit is formed on a wafer having an insulating film by a known method such as a resist, and then a metal-containing layer is formed by a method such as plating, a sputtering method, a CVD method, and a molecular beam epitaxy (MBE) method.

Examples of the present treatment method include a method in which an object to be treated containing a metal-containing substance is brought into contact with the treatment liquid. This makes it possible to clean the object to be treated (to remove residues on the object to be treated; and the like) or to remove one or more metal-containing substances contained in the object to be treated.

More specific examples of the treatment method include a cleaning method in which residues adhering to an object to be treated are removed using the treatment liquid, a CMP treating method in which an object to be treated as an object to be polished is polished using the treatment liquid containing abrasive grains, an etching method in which metal-containing substances on an object to be treated are dissolved and removed using the treatment liquid, a pretreatment method in which the treatment liquid is applied on a semiconductor substrate before a step of forming a resist film using an actinic ray-sensitive or radiation-sensitive composition, and a method in which a semiconductor substrate is subjected to a rinsing treatment method using the treatment liquid.

Among the present treatment methods, a semiconductor substrate cleaning method, a semiconductor substrate CMP-treating method, and a semiconductor substrate etching method will be described in detail below.

[First Aspect: Method for Cleaning Semiconductor Substrate]

A first aspect of the present treatment method is a method for cleaning a semiconductor substrate (hereinafter also referred to as a “main cleaning method”), which includes a cleaning step of cleaning the semiconductor substrate by bringing the treatment liquid into contact with the semiconductor substrate.

In the present cleaning method, a method of bringing the treatment liquid into contact with the semiconductor substrate is not particularly limited, and examples thereof include a method in which an object to be treated is immersed in a treatment liquid charged in a tank, a method in which a treatment liquid is sprayed onto an object to be treated, a method in which a treatment liquid is flown onto an object to be treated, and a combination thereof. From the viewpoint of residue removing properties, the method in which an object to be treated is immersed in the treatment liquid is preferable.

As a method for cleaning the semiconductor substrate, either a single-wafer method or a batch method may be adopted. The single-wafer method is a method of treating semiconductor substrates one by one, and the batch method is a method of treating a plurality of semiconductor substrates at the same time.

The temperature of the treatment liquid used as a cleaning liquid for cleaning a semiconductor substrate is not particularly limited as long as it is a temperature usually used in this field. Cleaning is often performed at room temperature (25° C.), but any temperature can be selected for the purpose of improving cleaning properties and/or suppressing a damage to members. For example, the temperature of the treatment liquid is preferably 10° C. to 60° C., and more preferably 15° C. to 50° C.

The cleaning time in cleaning the semiconductor substrate cannot be unequivocally determined since it depends on types and contents of the components included in the treatment liquid, but practically, the cleaning time is preferably 10 seconds to 2 minutes, more preferably 20 seconds to 1 minute and 30 seconds, and still more preferably 30 seconds to 1 minute.

The supply amount (supply rate) of the treatment liquid in the cleaning step for the semiconductor substrate is not particularly limited, but is preferably 50 to 5,000 mL/min, and more preferably 500 to 2,000 mL/min.

In the cleaning of the semiconductor substrate, a mechanical stirring method may be used in order to further improve the cleaning ability of the treatment liquid.

Examples of the mechanical stirring method include a method of circulating a treatment liquid on a semiconductor substrate, a method of flowing or spraying a treatment liquid on a semiconductor substrate, and a method of stirring a treatment liquid with an ultrasonic or a megasonic.

After cleaning the semiconductor substrate, a step of rinsing and cleaning the semiconductor substrate with a rinsing liquid (hereinafter referred to as a “rinsing step”) may be performed.

The rinsing step is preferably a step which is performed continuously subsequently after the cleaning step for the semiconductor substrate, and involves performing rinsing with a rinsing liquid (rinsing solvent) over 5 seconds to 5 minutes. The rinsing step may be performed using the above-mentioned mechanical stirring method.

Examples of the rinsing liquid include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8 (aqueous ammonium hydroxide that has been diluted, and the like) may be used. Moreover, the semiconductor substrate may be rinsed using the treatment liquid as the rinsing liquid.

As a method of bringing the rinsing liquid into contact with the semiconductor substrate, the above-mentioned method of bringing the treatment liquid into contact with the semiconductor substrate can be similarly applied.

In addition, after the rinsing step, a drying step of drying the semiconductor substrate may be performed.

Examples of the drying method include, but not limited to, a spin drying method, examples of the drying method include a spin drying method, a method of flowing a dry gas onto a semiconductor substrate, a method of heating a substrate by a heating means such as a hot plate and an infrared lamp, a Marangoni drying method, a Rotagoni drying method, an isopropyl alcohol (IPA) drying method, and any combinations thereof.

[Second Aspect: CMP Treating Method]

A second aspect of the present treatment method is a CMP treating method (hereinafter also referred to as “the present CMP method”) in which an object to be treated is polished using the treatment liquid. More specifically, the present CMP method is a treatment method including a step of bringing a surface to be polished of an object to be treated (an object to be polished) into contact with a polishing pad attached to a polishing platen while supplying the treatment liquid containing colloidal silica or abrasive grains (hereinafter also referred to as “the present polishing liquid”) to the polishing pad, and relatively moving the object to be polished and the polishing pad to polish the surface to be polished to obtain a polished object to be polished.

The object to be polished to which the present CMP method can be applied is not particularly limited, and examples thereof include the above-mentioned object to be treated, and a semiconductor substrate having at least one metal-containing layer selected from the group consisting of a copper-containing layer, a W-containing layer, and a Co-containing layer is preferable.

As an example of a configuration of the object to be polished, a configuration in which the object to be polished includes a substrate, an interlayer insulating film having a groove (for example, a groove for a wiring line) arranged on the substrate, a barrier layer arranged along the shape of the groove, and a metal-containing film arranged so that the groove is filled therewith may be mentioned. The metal-containing film with which the groove is filled is arranged at a position higher than an opening of the groove to further overflow. A portion of the metal-containing film, which is formed at a position higher than the opening of the groove, is referred to as a bulk layer.

By polishing the surface to be treated, which is a surface of the bulk layer, and performing the polishing until the barrier layer is exposed on the surface to be polished, the bulk layer can be removed to obtain an object to be polished. The present CMP method may be a method having a step of removing a bulk layer exposed on a surface to be treated, using the present polishing liquid as a polishing liquid for the bulk layer.

Polishing of the bulk layer may be performed until the bulk layer is completely removed, or may be finished before the bulk layer is completely removed. That is, the polishing may be completed in the state where the bulk layer partially or completely covers the barrier layer.

In the object to be polished from which the bulk layer has been removed, the barrier layer and the metal-containing film are exposed on the surface to be treated. The present CMP method may have a step in which the barrier layer and the metal-containing film, each exposed on a surface to be treated, are polished at the same time, using the present polishing liquid as a polishing liquid for a barrier, and the interlayer insulating film is polished until it is exposed on the surface to be polished, thereby removing the barrier layer.

Furthermore, even after the interlayer insulating film is exposed on the surface to be polished, the polishing of the interlayer insulating film, the barrier layer arranged along the shape of the grooves of the interlayer insulating film, and/or the metal-containing film (wiring line) with which the grooves are filled may be intentionally or unavoidably continued. In addition, in the step of removing the barrier layer, the bulk layer that has not been completely removed may be polished and removed.

Moreover, in the step of removing the barrier layer, the barrier layer on the interlayer insulating film may be completely removed, or the barrier layer on the interlayer insulating film may be completely removed before the barrier layer is completely removed. That is, a polished object to be polished may be obtained by finishing the polishing in the state where the barrier layer partially or completely covers the interlayer insulating film.

Specific examples of the substrate include a semiconductor substrate consisting of a single layer and a semiconductor substrate consisting of multiple layers.

Examples of a commercially available products of the object to be polished to which the present CMP method is applied include SEMATECH 754TEG (manufactured by SEMATECH Inc.).

A known chemical mechanical polishing device (hereinafter also referred to as a “CMP device”) can be used as a polishing device with which the present CMP method can be carried out.

Examples of the CMP device include a CMP device having a holder for holding an object to be polished having a surface to be polished, and a polishing platen to which a polishing pad is attached (to which a motor or the like with a rotation speed being changeable is attached).

A polishing pressure in the present CMP method is preferably 0.1 to 5.0 psi, more preferably 0.5 to 3.0 psi, and still more preferably 1.0 to 3.0 psi from the viewpoint that generation of scratch-like defects of a surface to be polished can be suppressed and the surface to be polished after polishing is likely to be uniform. Furthermore, the polishing pressure means a pressure generated on a contact surface between the surface to be polished and the polishing pad.

A rotation speed of the polishing platen in the present CMP method is preferably 50 to 200 rpm, and more preferably 60 to 150 rpm.

Incidentally, in order to relatively move the object to be polished and the polishing pad, the holder may be rotated and/or rocked, the polishing platen may be rotated by planetary rotation, or a belt-shaped polishing pad may be moved linearly in one of longitudinal directions. Furthermore, the holder may be in any state of being fixed, rotating, or rocked. These polishing methods can be appropriately selected depending on a surface to be polished and/or a polishing device as long as the object to be polished and the polishing pad are relatively moved.

In the present CMP method, it is preferable to continuously supply the present polishing liquid to the polishing pad on the polishing platen by a pump or the like while polishing the surface to be polished. Although an amount of the present polishing liquid to be supplied is not limited, it is preferable that a surface of the polishing pad is always covered with the present polishing liquid.

For example, a supply rate of the polishing liquid is preferably 0.05 to 0.75 ml/(min·cm²), and more preferably 0.14 to 0.35 ml/(min·cm²) from the viewpoint that generation of scratch-like defects on a surface to be polished can be suppressed and the surface to be polished is likely to be uniform after polishing.

It is also preferable that the present CMP method has a cleaning step of cleaning the polished object to be polished, thus obtained, after the step of obtaining the polished object to be polished. Residues of polishing sludge generated by polishing and/or residues based on the components included in the present polishing liquid, and the like can be removed by the cleaning step.

The cleaning liquid used in the cleaning step is not limited, and examples thereof include a cleaning liquid that is alkaline (alkaline cleaning liquid), a cleaning liquid that is acidic (acidic cleaning liquid), water, and an organic solvent, and among these, the alkaline cleaning liquid is preferable from the viewpoint that the alkaline cleaning liquid has a residue removing property and can suppress the surface roughness of a surface to be polished after washing.

[Third Aspect: Method for Etching Semiconductor Substrate]

A third aspect of the present treatment method is a method having a step A for removing a metal-containing substance on an object to be treated, using the treatment liquid (hereinafter also referred to as “the present etching method”).

Specific examples of the method of the step A include a method of dissolving and removing the metal-containing substance on the object to be treated by bringing the treatment liquid into contact with the semiconductor substrate.

In the present etching method, the method of bringing the treatment liquid into contact with the semiconductor substrate is not particularly limited, and the method described in the first aspect can be applied.

The treatment time in the step A may be adjusted according to the method of bringing the treatment liquid into contact with the substrate and the temperature of the treatment liquid. The treatment time (a contact time between the treatment liquid and the object to be treated) is not particularly limited, but is preferably 10 seconds to 10 minutes, and more preferably 30 seconds to 2 minutes.

The temperature of the treatment liquid during the treatment is not particularly limited, but is preferably 10° C. to 75° C., and more preferably 20° C. to 60° C.

Specific examples of the aspect of the step A include a step A1 of subjecting a wiring line consisting of a metal-containing substance, arranged on a substrate, to a recess-etching treatment using a treatment liquid, a step A2 of removing a film on an outer edge of a substrate on which a film consisting of a metal-containing substance is arranged thereon using a treatment liquid, a step A3 of removing a metal-containing substance adhering to a back surface of a substrate on which a film consisting of a metal-containing substance is arranged using a treatment liquid, and a step A4 of removing a metal-containing substance on a substrate after dry-etching using a treatment liquid.

For the steps A1 to A4, the description in paragraphs [0049] to [0069] of WO2019/138814A, the contents of which are incorporated herein by reference, can be used.

The present treatment method may be carried out in combination before or after other steps performed in the method for manufacturing a semiconductor device. The present treatment method may be incorporated into other steps while carrying out the present treatment method, or the present treatment method may be incorporated into the other steps.

Examples of the other steps include a step of forming each structure such as a metal wire, a gate structure, a source structure, a drain structure, an insulating layer, a ferromagnetic layer, and/or a non-magnetic layer (layer formation, etching, chemical mechanical polishing, modification, and the like), a resist forming step, an exposure step and a removing step, a heat treatment step, a cleaning step, an inspecting step, and other steps.

The present treatment method may be performed at any stage of a back-end-of-the-line (BEOL) process, a middle-of-the-line (MOL) process, and a front-end-of-the-line (FEOL) process.

### EXAMPLES

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention. Therefore, the scope of the present invention should not be construed as being limited to Examples shown below.

In the following Examples, the pH of the treatment liquid was measured at 25° C. using a pH meter (manufactured by HORIBA, Ltd., model “F-74”) in accordance with JIS Z8802-1984.

Furthermore, in the production of treatment liquids of Examples and Comparative Examples, all of handling of a container, and production, filling, storage, and analytical measurement of the treatment liquids were performed in a clean room satisfying a level of ISO Class 2 or lower.

[Raw Material of Treatment Liquid]

The following compounds were used to produce the treatment liquid. Furthermore, as various components used in Examples, those all classified into a semiconductor grade or a high-purity grade equivalent thereto were used.

[Component A]

As the component A, compounds consisting of the following cations (A-1) to (A-4), (A-8), (A-12), (A-21), (A-32), (A-XT), and (A-X2), and a hydroxide ion as a counter ion were used.

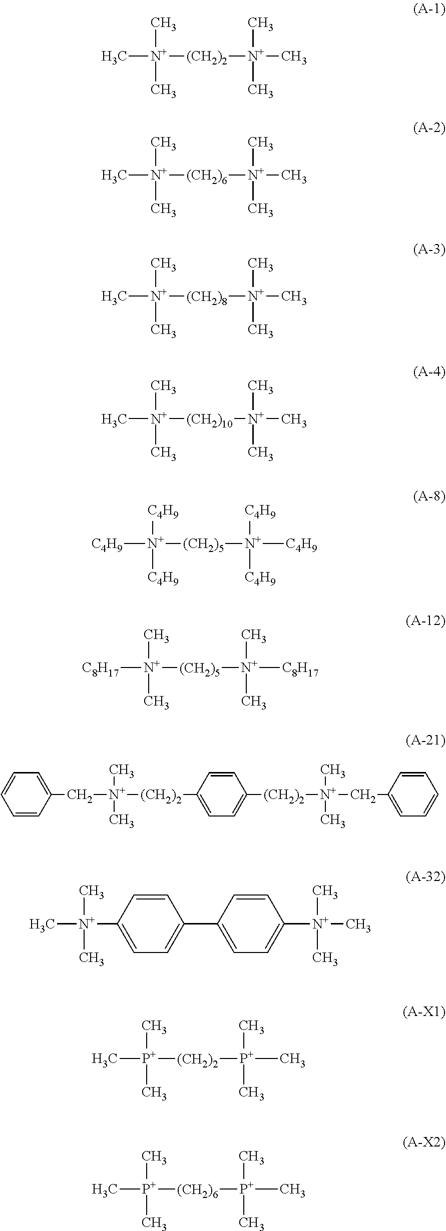

[Colloidal Silica]
PL1: Product name, manufactured by Fuso Chemical Co., Ltd., average primary particle diameter of 10 nm, aspect ratio of 1.8, degree of association of 2

[Organic Acid]
Citric acid

[Heteroaromatic Compounds]
BTA: Benzotriazole
5-MBTA: 5-Methyl-TH-benzotriazole

[Oxidizing Agent]
Hydrogen peroxide (H₂O₂)

[Surfactant]
W-1: Polyoxyethylene lauryl ether (C₁₂H₂₅(EO)₃OH)

[Amino Alcohol]
TEA: Triethanolamine

[Organic Solvent]
DEGEE: Diethylene glycol monoethyl ether

[HA Compound]
HA: Hydroxylamine

In addition, in a step of producing each treatment liquid in the present Example, either sulfuric acid (H₂SO₄) or diazabicycloundecene (DBU) was used as a pH adjuster. It should be noted that in Comparative Examples 1A and 1B, tetramethylammonium hydroxide (TMAH) was used, and in Comparative Examples 3A and 3B, either of sulfuric acid (H₂SO₄) and ammonia (NH₃) was used, as the pH adjuster.

In addition, commercially available ultrapure water (manufactured by FUJIFILM Wako Pure Chemical Corporation) was used as water.

### Examples 1A to 37A and Comparative Examples 1A to 3A

[Preparation of Polishing Liquid]

In Examples 1A to 37A and Comparative Examples 1A to 3A, polishing liquids were prepared.

A method for preparing the polishing liquid will be described by taking Example TA as an example.

Each raw material (or an aqueous solution thereof) of the compound (A-1), PL1 (colloidal silica), citric acid, benzotetrazole (BTA), and hydrogen peroxide was subjected to a filtration treatment through a high-density polyethylene filter. At this time, an aqueous solution of colloidal silica was filtered through a filter having a pore diameter of 0.1 μm, and the other raw materials (or aqueous solutions thereof) were filtered through a filter having a pore diameter of 0.02 μm.

After adding the raw materials and ultrapure water in amounts having the contents shown in Table 1, a pH adjuster was added to the mixture so that the pH of the prepared polishing liquid was 10.0. The obtained mixed solution was sufficiently stirred with a stirrer to obtain the polishing liquid of Example 1A.

According to the method for preparing the polishing liquid of Example TA, polishing liquids of Examples 2A to 37A and Comparative Examples 1A to 3A having the compositions shown in Table 1 were each produced.

In Table 1, the “Amount” column indicates a content (unit: % by mass) of each component with respect to the total mass of the treatment liquid. Furthermore, the content of each component in the table indicates a content of each component as a compound. For example, hydrogen peroxide was added in the state of an aqueous hydrogen peroxide solution in the preparation of the polishing liquid, but the description of the content in the “Hydrogen peroxide” column in the tables indicates a content of hydrogen peroxide (H₂O₂) itself included in the polishing liquid, not that of the aqueous hydrogen peroxide solution added to the polishing liquid.

The numerical value in the “Ratio A” column indicates a mass ratio of the content of the surfactant to the content of the component A (the content of the surfactant/the content of the component A).

The numerical value in the “Ratio B” column indicates a mass ratio of the content of the amino alcohol to the content of the component A (the content of the amino alcohol/the content of the component A).

The numerical value in the “pH of Polishing liquid” column indicates a pH of the polishing liquid at 25° C. measured by the pH meter.

The “Balance” in the “Water” column indicates that in the polishing liquids of each Example and each Comparative Example, the components shown in the table, and as desired, the components other than the pH adjuster added in such an amount that the pH of the polishing liquid is a numerical value in the “pH of Polishing liquid” column are water.

[Evaluation Test for Polishing Liquid]

The following evaluations were each performed using the obtained polishing liquids.

<Evaluation of Corrosion Prevention Performance>

A wafer (12 inches in diameter) having a metal film consisting of tungsten on the surface was cut to prepare each of 2 cm n wafer coupons. The thickness of the metal film was 20 nm. The wafer coupon was immersed in a sample (temperature: 45° C.) of each of polishing liquids of Examples or Comparative Examples produced by the method, and an immersion treatment was performed for 30 minutes under stirring at a stirring rotation speed of 250 rpm. A corrosion rate per unit time was calculated from a difference in the thickness of the metal film measured before and after the immersion treatment. From the obtained corrosion rate, the corrosion prevention performance of the polishing liquid was evaluated based on the following evaluation standard.

Furthermore, the lower the corrosion rate, the better the corrosion prevention performance of the polishing liquid.

AA: The corrosion rate is 1 Å/min or less

A: The corrosion rate is more than 1 Å/min and 2 Å/min or less

B: The corrosion rate is more than 2 Å/min and 3 Å/min or less

C: The corrosion rate is more than 3 Å/min and less than 5 Å/min

D: The corrosion rate is 5 Å/min or more

<Evaluation of Polishing Flaw Suppressing Performance>

A wafer was polished under the conditions that a polishing pressure was set to 2.0 psi and a supply rate of the polishing liquid was set to 200 ml/min, using FREX300SII (polishing device).

Incidentally, in the wafer, an interlayer insulating film consisting of silicon nitride was formed on a silicon substrate having a diameter of 12 inches, and the interlayer insulating film was engraved with a groove having a line-and-space pattern consisting of a line of 9 μm and a space of 1 μm. A barrier layer (material: TiN, film thickness: 10 nm) was arranged along the shape of the groove, and the groove was filled with Co. Further, a bulk layer consisting of Co, having a film thickness of 150 to 300 nm, was formed on an upper part of a line-and-space part so that Co overflowed from the groove.

First, Co (bulk) of the non-wiring part was completely polished using CSL5152C (trade name, manufactured by FUJIFILM Planar Solutions, LLC) as bulk polishing liquid, and then polishing was further performed for 10 seconds. Thereafter, polishing was performed for 1 minute under the same conditions, using each of the polishing liquids of Examples or Comparative Examples. The wafer after polishing was cleaned with an alkaline cleaning liquid (pCMP liquid, trade name “CL9010”, manufactured by Fujifilm Electronics Materials Co., Ltd.)) for 1 minute in a cleaning unit, further subjected to isopropanol (IPA) cleaning for 30 minutes, and then subjected to a drying treatment.

The obtained wafer was measured by a defect detection device, coordinates where defects having a major diameter of 0.06 μm or more were present were identified, and then the types of the defects at the identified coordinates were classified. The number of polishing flaws (scratch-like defects) detected on the wafer was compared with the following categories to evaluate the polishing flaw suppressing performance of each polishing liquid.

It can be evaluated that the smaller the number of polishing flaws, the better the polishing flaw suppressing performance.

(Evaluation Standard)

A: The number of polishing flaws is 3 or less

B: The number of polishing flaws is 4 to 6

C: The number of polishing flaws is 7 to 10

D: The number of polishing flaws is 11 or more

The tables below show the results of the evaluation tests performed using the polishing liquid of each of Examples or Comparative Examples.

TABLE 1

| | Composition of polishing liquid | | | | | | | | | | |
|---|---|---|---|---|---|---|---|---|---|---|---|
| | | | | | | | Heteroaromatic | | | | |
| | Composition A | | Colloidal silica | | Organic acid | | compound | | Hydrogen | Surfactant | |
| | Type | Amount | Type | Amount | Type | Amount | Type | Amount | peroxide | Type | Amount |
| Example 1A | A-1 | 0.50% | PL1 | 1.5% | Citric acid | 0.05% | BTA | 0.0001% | 0.01% | | |
| Example 2A | A-2 | 0.50% | PL1 | 1.5% | Citric acid | 0.05% | BTA | 0.0001% | 0.01% | | |
| Example 3A | A-X1 | 0.50% | PL1 | 1.5% | Citric acid | 0.05% | BTA | 0.0001% | 0.01% | | |
| Example 4A | A-X2 | 0.50% | PL1 | 1.5% | Citric acid | 0.05% | BTA | 0.0001% | 0.01% | | |
| Example 5A | A-3 | 0.50% | PL1 | 1.5% | Citric acid | 0.05% | BTA | 0.0001% | 0.01% | | |
| Example 6A | A-4 | 0.50% | PL1 | 1.5% | Citric acid | 0.05% | BTA | 0.0001% | 0.01% | | |
| Example 7A | A-8 | 0.50% | PL1 | 1.5% | Citric acid | 0.05% | BTA | 0.0001% | 0.01% | | |
| Example 8A | A-12 | 0.50% | PL1 | 1.5% | Citric acid | 0.05% | BTA | 0.0001% | 0.01% | | |
| Example 9A | A-21 | 0.50% | PL1 | 1.5% | Citric acid | 0.05% | BTA | 0.0001% | 0.01% | | |
| Example 10A | A-32 | 0.50% | PL1 | 1.5% | Citric acid | 0.05% | BTA | 0.0001% | 0.01% | | |
| Example 11A | A-2 | 0.50% | PL1 | 1.5% | Citric acid | 0.05% | BTA | 0.0001% | 0.01% | | |
| Example 12A | A-2 | 0.50% | PL1 | 1.5% | Citric acid | 0.05% | BTA | 0.0001% | 0.01% | | |
| Example 13A | A-2 | 0.50% | PL1 | 1.5% | Citric acid | 0.05% | BTA | 0.0001% | 0.01% | | |
| Example 14A | A-2 | 0.50% | PL1 | 1.5% | Citric acid | 0.05% | BTA | 0.0001% | 0.01% | | |
| Example 15A | A-2 | 0.50% | PL1 | 1.5% | Citric acid | 0.05% | BTA | 0.0001% | 0.01% | | |
| Example 16A | A-2 | 0.50% | PL1 | 1.5% | Citric acid | 0.05% | BTA | 0.0001% | 0.01% | | |
| Example 17A | A-2 | 0.005% | PL1 | 1.5% | Citric acid | 0.05% | BTA | 0.0001% | 0.01% | | |
| Example 18A | A-2 | 0.02% | PL1 | 1.5% | Citric acid | 0.05% | BTA | 0.0001% | 0.01% | | |
| Example 19A | A-2 | 0.10% | PL1 | 1.5% | Citric acid | 0.05% | BTA | 0.0001% | 0.01% | | |
| Example 20A | A-2 | 1.00% | PL1 | 1.5% | Citric acid | 0.05% | BTA | 0.0001% | 0.01% | | |
| Example 21A | A-2 | 3.00% | PL1 | 1.5% | Citric acid | 0.05% | BTA | 0.0001% | 0.01% | | |
| Example 22A | A-2 | 5.00% | PL1 | 1.5% | Citric acid | 0.05% | BTA | 0.0001% | 0.01% | | |
| Example 23A | A-2 | 8.00% | PL1 | 1.5% | Citric acid | 0.05% | BTA | 0.0001% | 0.01% | | |
| Example 24A | A-2 | 12.00% | PL1 | 1.5% | Citric acid | 0.05% | BTA | 0.0001% | 0.01% | | |
| Example 25A | A-4 | 0.50% | PL1 | 1.5% | Citric acid | 0.05% | BTA | 0.0001% | 0.01% | W-1 | 0.0004% |
| Example 26A | A-4 | 0.50% | PL1 | 1.5% | Citric acid | 0.05% | BTA | 0.0001% | 0.01% | W-1 | 0.0008% |
| Example 27A | A-4 | 0.50% | PL1 | 1.5% | Citric acid | 0.05% | BTA | 0.0001% | 0.01% | W-1 | 0.002% |
| Example 28A | A-4 | 0.50% | PL1 | 1.5% | Citric acid | 0.05% | BTA | 0.0001% | 0.01% | W-1 | 0.006% |
| Example 29A | A-4 | 0.50% | PL1 | 1.5% | Citric acid | 0.05% | BTA | 0.0001% | 0.01% | W-1 | 0.03% |
| Example 30A | A-4 | 0.50% | PL1 | 1.5% | Citric acid | 0.05% | BTA | 0.0001% | 0.01% | W-1 | 0.10% |
| Example 31A | A-4 | 0.50% | PL1 | 1.5% | Citric acid | 0.05% | BTA | 0.0001% | 0.01% | W-1 | 1.00% |
| Example 32A | A-4 | 0.50% | PL1 | 1.5% | Citric acid | 0.05% | BTA | 0.0001% | 0.01% | | |
| Example 33A | A-4 | 0.50% | PL1 | 1.5% | Citric acid | 0.05% | BTA | 0.0001% | 0.01% | | |
| Example 34A | A-4 | 0.50% | PL1 | 1.5% | Citric acid | 0.05% | BTA | 0.0001% | 0.01% | | |
| Example 35A | A-4 | 0.50% | PL1 | 1.5% | Citric acid | 0.05% | BTA | 0.0001% | 0.01% | | |
| Example 36A | A-4 | 0.50% | PL1 | 1.5% | Citric acid | 0.05% | BTA | 0.0001% | 0.01% | | |
| Example 37A | A-4 | 0.50% | PL1 | 1.5% | Citric acid | 0.05% | BTA | 0.0001% | 0.01% | | |
| Comparative | — | — | PL1 | 1.5% | Citric acid | 0.05% | BTA | 0.0001% | 0.01% | | |
| Example 1A | | | | | | | | | | | |
| Comparative | A-8 | 0.50% | PL1 | 1.5% | Citric acid | 0.05% | BTA | 0.0001% | 0.01% | | |
| Example 2A | | | | | | | | | | | |
| Comparative | A-8 | 0.50% | PL1 | 1.5% | Citric acid | 0.05% | BTA | 0.0001% | 0.01% | | |
| Example 3A | | | | | | | | | | | |

TABLE 2

| | | | | | | | | Evaluation | |
|---|---|---|---|---|---|---|---|---|---|
| | | | | | | | | | Polishing |
| | Composition of polishing liquid | | | | | | pH of | Corrosion | flaw |
| | Ratio | Amino alcohol | | Ratio | pH | | polishing | prevention | suppressing |
| | A | Type | Amount | B | adjuster | Water | liquid | performance | properties |
| Example 1A | | | | | H₂SO₄/DBU | Balance | 10.0 | B | A |
| Example 2A | | | | | H₂SO₄/DBU | Balance | 10.0 | B | A |
| Example 3A | | | | | H₂SO₄/DBU | Balance | 10.0 | B | A |
| Example 4A | | | | | H₂SO₄/DBU | Balance | 10.0 | B | A |
| Example 5A | | | | | H₂SO₄/DBU | Balance | 10.0 | B | A |
| Example 6A | | | | | H₂SO₄/DBU | Balance | 10.0 | B | B |
| Example 7A | | | | | H₂SO₄/DBU | Balance | 10.0 | A | A |
| Example 8A | | | | | H₂SO₄/DBU | Balance | 10.0 | C | B |
| Example 9A | | | | | H₂SO₄/DBU | Balance | 10.0 | C | B |
| Example 10A | | | | | H₂SO₄/DBU | Balance | 10.0 | C | B |
| Example 11A | | | | | H₂SO₄/DBU | Balance | 7.0 | B | B |
| Example 12A | | | | | H₂SO₄/DBU | Balance | 8.0 | B | A |
| Example 13A | | | | | H₂SO₄/DBU | Balance | 9.0 | B | A |
| Example 14A | | | | | H₂SO₄/DBU | Balance | 11.0 | B | A |
| Example 15A | | | | | H₂SO₄/DBU | Balance | 12.0 | B | A |
| Example 16A | | | | | H₂SO₄/DBU | Balance | 13.5 | B | B |
| Example 17A | | | | | H₂SO₄/DBU | Balance | 10.0 | c | A |
| Example 18A | | | | | H₂SO₄/DBU | Balance | 10.0 | B | A |
| Example 19A | | | | | H₂SO₄/DBU | Balance | 10.0 | B | A |
| Example 20A | | | | | H₂SO₄/DBU | Balance | 10.0 | A | A |
| Example 21A | | | | | H₂SO₄/DBU | Balance | 10.0 | A | A |
| Example 22A | | | | | H₂SO₄/DBU | Balance | 10.0 | A | A |
| Example 23A | | | | | H₂SO₄/DBU | Balance | 10.0 | A | B |
| Example 24A | | | | | H₂SO₄/DBU | Balance | 10.0 | A | C |
| Example 25A | 1,250 | | | | H₂SO₄/DBU | Balance | 10.0 | B | A |
| Example 26A | 625 | | | | H₂SO₄/DBU | Balance | 10.0 | A | A |
| Example 27A | 250 | | | | H₂SO₄/DBU | Balance | 10.0 | AA | A |
| Example 28A | 83 | | | | H₂SO₄/DBU | Balance | 10.0 | AA | A |
| Example 29A | 17 | | | | H₂SO₄/DBU | Balance | 10.0 | AA | A |
| Example 30A | 5 | | | | H₂SO₄/DBU | Balance | 10.0 | AA | A |
| Example 31A | 0.5 | | | | H₂SO₄/DBU | Balance | 10.0 | A | A |
| Example 32A | | TEA | 0.10% | 5.00 | H₂SO₄/DBU | Balance | 10.0 | B | A |
| Example 33A | | TEA | 0.50% | 1.00 | H₂SO₄/DBU | Balance | 10.0 | B | A |
| Example 34A | | TEA | 1.00% | 0.50 | H₂SO₄/DBU | Balance | 10.0 | A | A |
| Example 35A | | TEA | 3.00% | 0.17 | H₂SO₄/DBU | Balance | 10.0 | A | A |
| Example 36A | | TEA | 5.00% | 0.10 | H₂SO₄/DBU | Balance | 10.0 | B | A |
| Example 37A | | TEA | 10.00% | 0.05 | H₂SO₄/DBU | Balance | 10.0 | B | B |
| Comparative | | | | | TMAH | Balance | 10.0 | D | C |
| Example 1A | | | | | | | | | |
| Comparative | | | | | H₂SO₄/DBU | Balance | 14.0 | D | C |
| Example 2A | | | | | | | | | |
| Comparative | | | | | H₂SO₄/NH₃ | Balance | 5.5 | D | D |
| Example 3A | | | | | | | | | |

From the results shown in the tables, it was confirmed that desired results could be obtained in a case of using the treatment liquid of the embodiment of the present invention as the polishing liquid.

By comparison of Examples 1A to 10A, it was confirmed that in a case where the polishing liquid includes compounds having the cations (A-1) to (A-4), (A-8), (A-X1), and (A-X2) as the component A, the corrosion prevention performance on the W-containing film is more excellent; in a case where the polishing liquid includes compounds having the cations (A-1) to (A-3), (A-8), (A-X1), and (A-X2), the polishing flaw suppressing properties are more excellent; and in a case where the polishing liquid includes compound having the cation (A-8), the corrosion prevention performance for the W-containing film is more excellent.

By comparison of Examples 11A to 16A, it was confirmed that in a case where the pH of the polishing liquid is 8.0 to 12.5 at 25° C., the polishing flaw suppressing properties are more excellent.

By comparison of Examples 2A and 17A to 20A, it was confirmed that in a case where the content of the component A is 0.01% by mass or more with respect to the total mass of the polishing liquid, the corrosion prevention performance for the W-containing film is more excellent; and in a case where the content of the component A is 0.8% by mass or more with respect to the total mass of the polishing liquid, the corrosion prevention performance for the W-containing film is more excellent.

In addition, by comparison of Examples 22A to 24A, it was confirmed that in a case where the content of the component A is 10% by mass or less with respect to the total mass of the polishing liquid, the polishing flaw suppressing properties are more excellent; and in a case where the content of the component A is 5% by mass or less with respect to the total mass of the polishing liquid, the polishing flaw suppressing properties are more excellent.

By comparison of Examples 25A to 31A, in a case where the polishing liquid includes a surfactant, it was confirmed that in a case where the content of the surfactant is 0.0005% by mass or more with respect to the total mass of the polishing liquid, the corrosion prevention performance for the W-containing film is more excellent; and in a case where the content of the surfactant is 0.001% to 0.5% by mass with respect to the total mass of the polishing liquid, the corrosion prevention performance for the W-containing film is more excellent.

In addition, by comparison of Examples 25A to 31A, in a case where the polishing liquid includes a surfactant, it was confirmed that in a case where the ratio A is 1,000 or less, the corrosion prevention performance for the W-containing film is more excellent; and in a case where the ratio A is 1 to 500, the corrosion prevention performance for the W-containing film is more excellent.

By comparison of Examples 32A to 37A, in a case where the polishing liquid includes an amino alcohol, it was confirmed that in a case where the content of the amino alcohol is 8% by mass or less with respect to the total mass of the polishing liquid, the polishing flaw suppressing properties are more excellent; and in a case where the content of the amino alcohol is 0.8% to 4% by mass with respect to the total mass of the polishing liquid, the corrosion prevention performance for the W-containing film is more excellent.

In addition, by comparison of Examples 32A to 37A, in a case where the polishing liquid includes an amino alcohol, it was confirmed that in a case where the ratio B is 0.08 or more, the polishing flaw suppressing properties are more excellent; and in a case where the ratio B is 0.12 to 0.8, the corrosion prevention performance for the W-containing film is more excellent.

### Examples 1B to 37B and Comparative Examples 1B to 3B

[Preparation of Etchant]

In Examples 1B to 37B and Comparative Examples 1B to 3B, etchants were prepared.

According to the method for preparing a polishing liquid of Example 1A, etchants of Examples 1B to 37B and Comparative Examples 1B to 3B having the compositions shown in Table 2 were each produced.

The “Balance” in the “Amount” column, the “Ratio A” column, the “Ratio B” column, and the “Water” column in Table 2 has the same meaning as each column in Table 1.

The “HA Compound” column shows hydroxylamine compounds.

The numerical value in the “pH of Etchant” column indicates a pH of the etchant measured by the pH meter at 25° C.

[Evaluation Test for Etchant]

The following evaluations were each performed using the obtained etchants.

<Evaluation of Corrosion Prevention Performance>

A wafer (12 inches in diameter) having a metal film consisting of tungsten on the surface was cut to prepare each of 2 cm ▭ wafer coupons. The thickness of the metal film was 20 nm. The wafer coupon was immersed in a sample (temperature: 45° C.) of each of the etchants of Examples or Comparative Examples produced by the method, and an immersion treatment was performed for 30 minutes under stirring at a stirring rotation speed of 250 rpm. A corrosion rate per unit time was calculated from a difference in the thickness of the metal film measured before and after the immersion treatment. From the obtained corrosion rate, the corrosion prevention performance of the etchant was evaluated based on the following evaluation standard.

Furthermore, the lower the corrosion rate, the better the corrosion prevention performance of the etchant.

A: The corrosion rate is 2 Å/min or less

B: The corrosion rate is more than 2 Å/min and 3 Å/min or less

C: The corrosion rate is more than 3 Å/min and less than 5 Å/min

D: The corrosion rate is 5 Å/min or more

<Evaluation of Residue Removal Performance>

A laminate having a film having a thickness of 1,000 angstroms (Å) and consisting of TiO₂, was prepared on a silicon wafer having a diameter of 300 mm. This laminate was immersed in a sample (temperature: 45° C.) of each treatment liquid of Examples and Comparative Examples for 5 minutes. The etching rate (Å/min) of the etchant was calculated based on a difference in the thickness of the TiO₂ film before and after immersion, and the residue removal performance of the etchant was evaluated from the obtained etching rate based on the following evaluation standard.

Furthermore, TiO₂ is one of the components of the residues generated in a case where a metal hard mask used for manufacturing the semiconductor substrate is plasma-etched. It can be evaluated that the higher the etching rate for TiO₂, the better the residue removal performance of the etchant.

A: The etching rate is 5 Å/min or more

B: The etching rate is 3 Å/min or more and less than 5 Å/min

C: The etching rate is 1 Å/min or more and less than 3 Å/min

D: The etching rate is less than 1 Å/min

The tables below show the results of the evaluation tests performed using the etchant of each of Examples or Comparative Examples.

TABLE 3

| | Composition of etchant | | | | | | | | | |
|---|---|---|---|---|---|---|---|---|---|---|
| | | | | | HA | | Heteroaromatic | | | |
| | Component A | | Organic solvent | | compound | | compound | | Surfactant | |
| | Type | Amount | Type | Amount | Type | Amount | Type | Amount | Type | Amount |
| Example 1B | A-1 | 0.50% | DEGEE | 68.00% | HA | 5.00% | 5-MBTA | 0.02% | | |
| Example 2B | A-2 | 0.50% | DEGEE | 68.00% | HA | 5.00% | 5-MBTA | 0.02% | | |
| Example 3B | A-X1 | 0.50% | DEGEE | 68.00% | HA | 5.00% | 5-MBTA | 0.02% | | |
| Example 4B | A-X2 | 0.50% | DEGEE | 68.00% | HA | 5.00% | 5-MBTA | 0.02% | | |
| Example 5B | A-3 | 0.50% | DEGEE | 68.00% | HA | 5.00% | 5-MBTA | 0.02% | | |
| Example 6B | A-4 | 0.50% | DEGEE | 68.00% | HA | 5.00% | 5-MBTA | 0.02% | | |
| Example 7B | A-8 | 0.50% | DEGEE | 68.00% | HA | 5.00% | 5-MBTA | 0.02% | | |
| Example 8B | A-12 | 0.50% | DEGEE | 68.00% | HA | 5.00% | 5-MBTA | 0.02% | | |
| Example 9B | A-21 | 0.50% | DEGEE | 68.00% | HA | 5.00% | 5-MBTA | 0.02% | | |
| Example 10B | A-32 | 0.50% | DEGEE | 68.00% | HA | 5.00% | 5-MBTA | 0.02% | | |
| Example 11B | A-2 | 0.50% | DEGEE | 68.00% | HA | 5.00% | 5-MBTA | 0.02% | | |
| Example 12B | A-2 | 0.50% | DEGEE | 68.00% | HA | 5.00% | 5-MBTA | 0.02% | | |
| Example 13B | A-2 | 0.50% | DEGEE | 68.00% | HA | 5.00% | 5-MBTA | 0.02% | | |
| Example 14B | A-2 | 0.50% | DEGEE | 68.00% | HA | 5.00% | 5-MBTA | 0.02% | | |
| Example 15B | A-2 | 0.50% | DEGEE | 68.00% | HA | 5.00% | 5-MBTA | 0.02% | | |
| Example 16B | A-2 | 0.50% | DEGEE | 68.00% | HA | 5.00% | 5-MBTA | 0.02% | | |
| Example 17B | A-2 | 0.005% | DEGEE | 68.00% | HA | 5.00% | 5-MBTA | 0.02% | | |
| Example 18B | A-2 | 0.02% | DEGEE | 68.00% | HA | 5.00% | 5-MBTA | 0.02% | | |
| Example 19B | A-2 | 0.10% | DEGEE | 68.00% | HA | 5.00% | 5-MBTA | 0.02% | | |
| Example 20B | A-2 | 1.00% | DEGEE | 68.00% | HA | 5.00% | 5-MBTA | 0.02% | | |
| Example 21B | A-2 | 3.00% | DEGEE | 68.00% | HA | 5.00% | 5-MBTA | 0.02% | | |
| Example 22B | A-2 | 5.00% | DEGEE | 68.00% | HA | 5.00% | 5-MBTA | 0.02% | | |
| Example 23B | A-2 | 8.00% | DEGEE | 68.00% | HA | 5.00% | 5-MBTA | 0.02% | | |
| Example 24B | A-2 | 12.00% | DEGEE | 68.00% | HA | 5.00% | 5-MBTA | 0.02% | | |
| Example 25B | A-4 | 0.50% | DEGEE | 68.00% | HA | 5.00% | 5-MBTA | 0.02% | W-1 | 0.0004% |
| Example 26B | A-4 | 0.50% | DEGEE | 68.00% | HA | 5.00% | 5-MBTA | 0.02% | W-1 | 0.0008% |
| Example 27B | A-4 | 0.50% | DEGEE | 68.00% | HA | 5.00% | 5-MBTA | 0.02% | W-1 | 0.002% |
| Example 28B | A-4 | 0.50% | DEGEE | 68.00% | HA | 5.00% | 5-MBTA | 0.02% | W-1 | 0.006% |
| Example 29B | A-4 | 0.50% | DEGEE | 68.00% | HA | 5.00% | 5-MBTA | 0.02% | W-1 | 0.03% |
| Example 30B | A-4 | 0.50% | DEGEE | 68.00% | HA | 5.00% | 5-MBTA | 0.02% | W-1 | 0.10% |
| Example 31B | A-4 | 0.50% | DEGEE | 68.00% | HA | 5.00% | 5-MBTA | 0.02% | W-1 | 1.00% |
| Example 32B | A-4 | 0.50% | DEGEE | 68.00% | HA | 5.00% | 5-MBTA | 0.02% | | |
| Example 33B | A-4 | 0.50% | DEGEE | 68.00% | HA | 5.00% | 5-MBTA | 0.02% | | |
| Example 34B | A-4 | 0.50% | DEGEE | 68.00% | HA | 5.00% | 5-MBTA | 0.02% | | |
| Example 35B | A-4 | 0.50% | DEGEE | 68.00% | HA | 5.00% | 5-MBTA | 0.02% | | |
| Example 36B | A-4 | 0.50% | DEGEE | 68.00% | HA | 5.00% | 5-MBTA | 0.02% | | |
| Example 37B | A-4 | 0.50% | DEGEE | 68.00% | HA | 5.00% | 5-MBTA | 0.02% | | |
| Comparative | — | — | DEGEE | 68.00% | HA | 5.00% | 5-MBTA | 0.02% | | |
| Example 1B | | | | | | | | | | |
| Comparative | A-8 | 0.50% | DEGEE | 68.00% | HA | 5.00% | 5-MBTA | 0.02% | | |
| Example 2B | | | | | | | | | | |
| Comparative | A-8 | 0.50% | DEGEE | 68.00% | HA | 5.00% | 5-MBTA | 0.02% | | |
| Example 3B | | | | | | | | | | |

TABLE 4

| | | | | | | | | Evaluation | |
|---|---|---|---|---|---|---|---|---|---|
| | Composition of etchant | | | | | | | Corrosion | Residue |
| | Ratio | Amino alcohol | | Ratio | | | pH of | prevention | removal |
| | A | Type | Amount | B | pH adjuster | Water | etchant | performance | performance |
| Example 1B | | | | | H₂SO₄/DBU | Balance | 10.0 | B | A |
| Example 2B | | | | | H₂SO₄/DBU | Balance | 10.0 | B | A |
| Example 3B | | | | | H₂SO₄/DBU | Balance | 10.0 | B | A |
| Example 4B | | | | | H₂SO₄/DBU | Balance | 10.0 | B | A |
| Example 5B | | | | | H₂SO₄/DBU | Balance | 10.0 | B | A |
| Example 6B | | | | | H₂SO₄/DBU | Balance | 10.0 | B | B |
| Example 7B | | | | | H₂SO₄/DBU | Balance | 10.0 | A | A |
| Example 8B | | | | | H₂SO₄/DBU | Balance | 10.0 | C | B |
| Example 9B | | | | | H₂SO₄/DBU | Balance | 10.0 | C | B |
| Example 10B | | | | | H₂SO₄/DBU | Balance | 10.0 | C | B |
| Example 11B | | | | | H₂SO₄/DBU | Balance | 7.0 | B | B |
| Example 12B | | | | | H₂SO₄/DBU | Balance | 8.0 | A | A |
| Example 13B | | | | | H₂SO₄/DBU | Balance | 9.0 | A | A |
| Example 14B | | | | | H₂SO₄/DBU | Balance | 11.0 | A | A |
| Example 15B | | | | | H₂SO₄/DBU | Balance | 12.0 | B | B |
| Example 16B | | | | | H₂SO₄/DBU | Balance | 13.5 | C | B |
| Example 17B | | | | | H₂SO₄/DBU | Balance | 10.0 | C | A |
| Example 18B | | | | | H₂SO₄/DBU | Balance | 10.0 | B | A |
| Example 19B | | | | | H₂SO₄/DBU | Balance | 10.0 | B | A |
| Example 20B | | | | | H₂SO₄/DBU | Balance | 10.0 | A | A |
| Example 21B | | | | | H₂SO₄/DBU | Balance | 10.0 | A | A |
| Example 22B | | | | | H₂SO₄/DBU | Balance | 10.0 | A | A |
| Example 23B | | | | | H₂SO₄/DBU | Balance | 10.0 | A | B |
| Example 24B | | | | | H₂SO₄/DBU | Balance | 10.0 | A | C |
| Example 25B | 1,250 | | | | H₂SO₄/DBU | Balance | 10.0 | B | A |
| Example 26B | 625 | | | | H₂SO₄/DBU | Balance | 10.0 | B | A |
| Example 27B | 250 | | | | H₂SO₄/DBU | Balance | 10.0 | B | A |
| Example 28B | 83 | | | | H₂SO₄/DBU | Balance | 10.0 | A | A |
| Example 29B | 17 | | | | H₂SO₄/DBU | Balance | 10.0 | A | A |
| Example 30B | 5 | | | | H₂SO₄/DBU | Balance | 10.0 | B | A |
| Example 31B | 0.5 | | | | H₂SO₄/DBU | Balance | 10.0 | B | B |
| Example 32B | | TEA | 0.10% | 5.00 | H₂SO₄/DBU | Balance | 10.0 | B | A |
| Example 33B | | TEA | 0.50% | 1.00 | H₂SO₄/DBU | Balance | 10.0 | B | A |
| Example 34B | | TEA | 1.00% | 0.50 | H₂SO₄/DBU | Balance | 10.0 | A | A |
| Example 35B | | TEA | 3.00% | 0.17 | H₂SO₄/DBU | Balance | 10.0 | A | A |
| Example 36B | | TEA | 5.00% | 0.10 | H₂SO₄/DBU | Balance | 10.0 | B | A |
| Example 37B | | TEA | 10.00% | 0.05 | H₂SO₄/DBU | Balance | 10.0 | B | B |
| Comparative | | | | | TMAH | Balance | 10.0 | D | C |
| Example 1B | | | | | | | | | |
| Comparative | | | | | H₂SO₄/DBU | Balance | 14.0 | D | C |
| Example 2B | | | | | | | | | |
| Comparative | | | | | H₂SO₄/NH₃ | Balance | 5.5 | D | D |
| Example 3B | | | | | | | | | |

From the results shown in the tables, it was confirmed that desired results could be obtained in a case of using the treatment liquid of the embodiment of the present invention as the etchant.

By comparison of Examples 1B to 10B, it was confirmed that in a case where the etchant includes compounds having the cations (A-1) to (A-4), (A-8), (A-X1), and (A-X2) as the component A, the corrosion prevention performance on the W-containing film is more excellent; in a case where the polishing liquid includes compounds having the cations (A-1) to (A-3), (A-8), (A-X1), and (A-X2), the residue removal performance is more excellent; and in a case where the polishing liquid includes compound having the cation (A-8), the corrosion prevention performance for the W-containing film is more excellent.

By comparison of Examples 11B to 16B, it was confirmed that in a case where the pH of the etchant was 8.0 to 11.5 at 25° C., the residue removal performance was more excellent.

By comparison of Examples 2B and 17B to 20B, it was confirmed that in a case where the content of the component A is 0.01% by mass or more with respect to the total mass of the etchant, the corrosion prevention performance for the W-containing film is more excellent; and in a case where the content of the component A is 0.8% by mass or more with respect to the total mass of the etchant, the corrosion prevention performance for the W-containing film is more excellent.

In addition, by comparison of Examples 22B to 24B, it was confirmed that in a case where the content of the component A is 10% by mass or less with respect to the total mass of the etchant, the residue removal performance is more excellent; and in a case where the content of the component A is 5% by mass or less with respect to the total mass of the etchant, the residue removal performance is more excellent.

By comparison of Examples 25B to 31B, in a case where the etchant includes a surfactant, it was confirmed that in a case where the content of the surfactant is 0.5% by mass or less with respect to the total mass of the etchant, the residue removal performance is more excellent; and in a case where the content of the surfactant is 0.005% to 0.05% by mass with respect to the total mass of the etchant, the corrosion prevention performance for the W-containing film is more excellent.

In addition, by comparison of Examples 25B to 31B, in a case where the etchant includes a surfactant, it was confirmed that in a case where the ratio A is 1 or more, the residue removal performance is more excellent; and in a case where the ratio A is 10 to 100, the corrosion prevention performance for the W-containing film is more excellent.

By comparison of Examples 32B to 37B, in a case where the etchant includes an amino alcohol, it was confirmed that in a case where the content of the amino alcohol is 8% by mass or less with respect to the total mass of the etchant, the residue removal performance is more excellent; and in a case where the content of the surfactant is 0.8% to 4% by mass with respect to the total mass of the etchant, the corrosion prevention performance for the W-containing film is more excellent.

In addition, by comparison of Examples 32B to 37B, in a case where the etchant includes an amino alcohol, it was confirmed that in a case where the ratio B is 0.08 or more, the residue removal performance is more excellent; and in a case where the ratio B is 0.12 to 0.8, the corrosion prevention performance for the W-containing film is more excellent.

What is claimed is:

1. A treatment liquid for a semiconductor substrate, comprising:
a component A having two or more onium structures in a molecule; and
water,
wherein the treatment liquid has a pH of 6.0 to 13.5 at 25° C.

2. The treatment liquid according to claim 1,
wherein the onium structure is a structure selected from the group consisting of an ammonium structure, a phosphonium structure, and a sulfonium structure.

3. The treatment liquid according to claim 1,
wherein the onium structure is a structure selected from the group consisting of an ammonium structure and a phosphonium structure.

4. The treatment liquid according to claim 1,
wherein the onium structure is an ammonium structure.

5. The treatment liquid according to claim 1,
wherein the component A is a compound represented by General Formula (I) or (II), 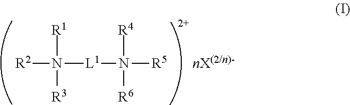
in General Formula (I), R¹ to R⁶ each independently represent a monovalent organic group, two of R¹ to R⁶ may be bonded to each other, L¹ represents a divalent linking group, n represents 1 or 2, and X^{(2/n)-} represents a (2/n)-valent counterion, 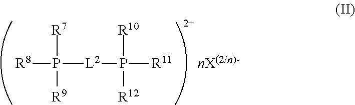
in General Formula (II), R⁷ to R¹² each independently represent a monovalent organic group, two of R⁷ to R¹² may be bonded to each other, L² represents a divalent linking group, n represents 1 or 2, and X^{(2/n)-} represents a (2/n)-valent counterion.

6. The treatment liquid according to claim 5,
wherein in General Formulae (I) and (II), n represents 2 and X^{(2/n)-} represents a hydroxide ion.

7. The treatment liquid according to claim 5,
wherein the component A is the compound represented by General Formula (I).

8. The treatment liquid according to claim 1,
wherein a content of the component A is 0.1% to 5% by mass with respect to a total mass of the treatment liquid.

9. The treatment liquid according to claim 1, further comprising an organic acid or an organic alkali.

10. The treatment liquid according to claim 1, further comprising an anticorrosive agent.

11. The treatment liquid according to claim 10,
wherein the anticorrosive agent includes a heteroaromatic compound.

12. The treatment liquid according to claim 11,
wherein the heteroaromatic compound is at least one selected from the group consisting of a tetrazole compound, a triazole compound, an imidazole compound, and a pyrazole compound.

13. The treatment liquid according to claim 10,
wherein the anticorrosive agent includes at least one hydroxylamine compound selected from the group consisting of hydroxylamine, a hydroxylamine derivative, and salts thereof.

14. The treatment liquid according to claim 1, further comprising an organic solvent.

15. The treatment liquid according to claim 1, further comprising a surfactant.

16. The treatment liquid according to claim 1,
wherein the semiconductor substrate has a metal-containing substance including at least one selected from the group consisting of copper, tungsten, and cobalt.

17. The treatment liquid according to claim 1, further comprising colloidal silica.

18. The treatment liquid according to claim 1, further comprising colloidal silica having an average primary particle diameter of 3 to 20 nm.

19. A chemical mechanical polishing method comprising a step of bringing a surface to be polished of an object to be polished into contact with a polishing pad attached to a polishing platen while supplying the treatment liquid according to claim 17 to the polishing pad, and relatively moving the object to be polished and the polishing pad to polish the surface to be polished, thereby obtaining a polished object to be polished.

20. A method for treating a semiconductor substrate, comprising a step of removing a metal-containing substance on the semiconductor substrate using the treatment liquid according to claim 1.
